(19) United States
(12) Patent Application Publication
(10) Pub. No.: US 2007/0224811 A1
(43) Pub. Date: Sep. 27, 2007

(54) Substrate processing method and substrate processing apparatus

(76) Inventors: Xinming Wang, Tokyo (JP); Akira Owatari, Tokyo (JP); Haruko Ono, Tokyo (JP); Tomoatsu Ishibashi, Tokyo (JP); Daisuke Takagi, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 11/724,305

(22) Filed: Mar. 15, 2007

(30) Foreign Application Priority Data
Mar. 16, 2006 (JP) 2006-73572
Jun. 16, 2006 (JP) 2006-167867

(51) Int. Cl. H01L 21/44; C25D 13/00

(52) U.S. Cl. 438/678; 438/906; 156/345.21; 204/622

(57) ABSTRACT

A substrate processing method can completely remove a corrosion inhibitor and/or a metal complex from a surface of a substrate prior to catalyst application processing and/or electroless plating, and can form a protective film having a uniform thickness on the surface of interconnects. The substrate processing method includes preparing a substrate having metal interconnects formed in an electric insulator, carrying out pre-processing of the substrate by bringing a cleaning member into contact with the front surface or both surfaces of the substrate in a wet state and moving them relative to each other while supplying a pre-processing liquid to the front surface or both surfaces of the substrate, and then forming a protective film selectively on surfaces of the metal interconnects by bringing the front surface of the substrate into contact with an electroless plating solution.

### BACKGROUND OF THE INVENTION

1. Field of the Invention

The present invention relates to a substrate processing method and a substrate processing apparatus, and more particularly to a substrate processing method and a substrate processing apparatus useful for forming a protective film or magnetic film by electroless plating selectively of, e.g., an alloy on exposed surfaces of embedded interconnects of a conductive material, such as copper, silver or the like, embedded in fine interconnect recesses formed in a surface of a substrate, such as a semiconductor wafer, to cover the interconnects. A substrate processing method and a substrate processing apparatus of the present invention is also applied to a magnetic film manufacturing process, such as MRAM, and a flat panel manufacturing process.

2. Description of the Related Art

As a process for forming interconnects in a semiconductor device, the so-called “damascene process”, which comprises embedding an interconnect material (metal) into interconnect recesses, such as trenches and via holes, is coming into practical use. According to this process, aluminum or, more recently a metal such as copper or silver, is embedded into trenches and via holes previously formed in an insulating film (interlevel dielectric layer). Thereafter, extra metal is removed by chemical mechanical polishing (CMP) so as to flatten a surface of the substrate.

With the recent accelerated progress toward higher-speed and finer semiconductor devices, the damascene process (filling of interconnects) using copper interconnects, instead of aluminum interconnects, and a low-dielectric constant inter level dielectric film material (low-K material) is becoming increasingly important. To increase the electromigration (EM) resistance of copper interconnects is essential for enhancement of the reliability of a semiconductor device. In this regard, the selective formation of a cobalt (Co) alloy film on copper interconnects has proven to produce a prominent effect on improvement in the EM resistance. Such a cobalt alloy film, if it could fully perform the function of preventing diffusion of copper or oxygen (O₂), would make it possible to omit a capping layer, composed of an insulating material having a high dielectric constant, which is used in the conventional process. A further lowering of the effective dielectric constant between interconnect layers can therefore be expected. With regard to electroless plating, it has the inherent characteristic of forming a plated film selectively only on a metal when the plating is carried out on a surface in which the metal and an insulating material are co-present. Electroless plating may therefore be regarded as an optimal method for forming a cobalt alloy film on copper interconnects. As will be appreciated from the above, the (electroless capping plating) technology of forming a cobalt alloy film by electroless plating is a most promising new process technology for establishing next-generation high-reliability copper interconnects.

FIG. 1A shows a conventional damascene copper-interconnect structure. The adhesion between copper interconnects 513 and an adjacent insulating capping layer 514 of, e.g., SiN, SiC or SiCN is generally low as compared to adhesion between metals. Therefore, migration of atoms tends to be more active at the interface between the copper interconnects 513 and the insulating capping layer 514 than in the copper interconnects 513 or at the interface between the copper interconnects 513 and a barrier metal layer 515 surrounding the copper interconnects 513. As the copper interconnects 513 become finer and a current density in the copper interconnects 513 increases accordingly, the boundary between the copper interconnects 513 and the insulating capping layer 514 is most likely to be a path of migration of atoms, and there is a high probability of the formation of defects (voids) at the interface due to electromigration.

A proposed countermeasure is to provide a new alloy thin film 516 between the copper interconnects 513 and the insulating capping layer 514, as shown in FIG. 1B. The alloy thin film 516 is called a capping metal. The capping metal 516 has good adhesion both with the copper interconnects 513 and with the insulating capping layer 514. The formation of the capping metal 516 can therefore considerably improve the EM resistance of the copper interconnects 513. If the capping metal 516 is made to have sufficient resistance to diffusion of copper and oxygen (O₂), it then becomes possible to use it as a protective film 517 in place of the insulating capping layer 514 currently used, as shown in FIG. 1C. By not providing the insulating capping layer 514, which generally has a high dielectric constant, the charge capacity (C) between interconnect layers can be lowered. This can reduce an RC delay in circuits and thus contribute to speeding-up of signal transmission. Furthermore, noise can be reduced and generation of heat can be lowered.

In a general process for forming such a protective film 517 selectively on surfaces of copper interconnects 513, the surfaces of the copper interconnects 513 in an insulating film 518 is first exposed by CMP, as shown in FIG. 2A. A copper oxide film 519a is possibly formed on the surfaces of the copper interconnects 513 after CMP, and a residue 519b may remain on the insulating film 518. The surface of the substrate is therefore cleaned to remove the copper oxide film 519a and the residue 519b, as shown in FIG. 2B. Next, as shown in FIG. 2C, a catalyst (nuclei) 521, such as Pd, is applied to the surfaces of the copper interconnects 513. Thereafter, electroless COWP plating, for example, is carried out on the substrate surface to form a protective film 517 of a CoWP alloy selectively on the surfaces of the copper interconnects 513, as shown in FIG. 2D. A metal residue 523 may remain on a surface of the protective film 517 or the insulating film 518 after the electroless plating.

Post-plating cleaning of the substrate surface is then carried out to remove the metal residue 523 remaining on the protective film 517 or on the insulating film 518, as shown in FIG. 2E. Thereafter, the substrate surface is cleaned with pure water and then dried to stabilize the surface of the protective film 517, as shown in FIG. 2F.

There are cases where a particular process step is added or deleted to or from between process steps depending on the characteristics and the intended use of an object to be plated. Some basic process steps will now be described below.

Unlike electroplating as employed for the formation of damascene copper interconnects, electroless plating does not involve supply of electrons from the outside but simply involves immersing a plating object in a plating solution containing a metal ion to reduce the metal ion and deposit the metal as a metal film. For the reduction of the metal ion, the plating solution must contain, besides the metal ion, a reducing component that emits electrons. The following are basic chemical reaction formulae in the case of depositing a film of a CoWP (cobalt, tungsten, phosphorus) alloy in a plating solution system using a hypophosphite as a reducing agent:
(a) Hypophosphite ion oxidation reaction
   H₂PO₂⁻+OH→H₂PO₃⁻+H+e⁻
(b) Cobalt ion reduction reaction
   Co₂+2H₂PO₂⁻+OH⁻→Co+H₂PO₃⁻+H₂
(c) Phosphorus ion reduction reaction
   H₂PO₂⁻+e⁻→P↓+2OH⁻
(d) Tungsten ion reduction reaction
   WO₂²⁺+6H₂PO₂⁻+4H₂O→W+6H₂PO₃⁻+3H₂+2H⁺
(e) Hydrogen-forming reaction
   H⁺+e⁻+H→H₂↑

As shown by the formulae, the hypophosphite as a reducing agent emits electrons through the oxidation reaction, while cobalt, phosphorus and tungsten ions receive the electrons and a eutectoid reaction takes place, forming an alloy film. The hydrogen reduction reaction usually proceeds in parallel with the eutectoid reaction.

Besides the above-described hypophosphite, an organic compound dimethylamine borane (DMAB) can be mentioned as a typical reducing agent for use in a plating solution. A plating solution using DMAB as a reducing agent shows a behavior different from that of a plating solution using a hypophosphite.

For the initiation of metal deposition on a coating surface by electroless plating, it is essential that the coating surface initially have a sufficient catalytic activity for the oxidation reaction of a reducing agent. Copper shows a very low catalytic activity for the anodic oxidation reaction of hypophosphite. Accordingly, a plating reaction does not theoretically take place on a copper surface. Therefore, in order to deposit a cobalt alloy on a copper surface, Pd having a high catalytic activity is generally applied to the copper surface. Thus, before initiating a plating reaction, a copper coating surface is subjected to catalytic processing with a pre-processing solution containing a Pd ion. The catalytic processing is based on a substitution reaction whose reaction formulae are as follows:
Cu→Cu²⁺+e⁻
Pd²⁺+e⁻→Pd

Pd usually does not cause a substitution reaction on a surface of an insulating low-k material, such as SiO₂ or SiOC. Accordingly, an electroless plating reaction occurs only on copper interconnects, allowing a film to be formed selectively on the copper interconnects.

As described above, electroless plating using a Pd catalyst theoretically causes selective film formation on copper interconnects. As shown in FIG. 2A, however, there are cases where the slurry residue 519b remains on the insulating film (inter level dielectric layer) 518 after CMP, the copper oxide film 519a is formed on the copper interconnect 513, or impurities such as watermarks remain on the substrate. If a Pd substitution reaction or a plating reaction occurs on such impurities, the resulting extraordinary deposits can cause a leak between interconnects and will increase surface defects. It is therefore essential for enhanced process performance to carry out appropriate cleaning processing of a surface of a substrate before or after plating.

In the case of copper interconnects, embedded copper interconnects have exposed surfaces after performing a flattening processing. When an additional embedded interconnect structure is formed on such interconnects-exposed surface of a substrate, the following problems may be encountered. For example, during formation of a new SiO₂ in a sequence process for forming an interlevel dielectric layer, exposed surfaces of pre-formed interconnects are likely to be oxidized. Further, upon etching of the SiO₂ for formation of via holes, the pre-formed interconnects exposed on bottoms of via holes can be contaminated with an etchant, a peeled resist, and the like.

In view of this, as described above, it has been proposed to selectively cover surfaces of exposed interconnects with a film of Co (Cobalt), a Co alloy, Ni (Nickel) or a Ni alloy, exhibiting a good adhesion to an interconnect material, such as copper or silver, and having a low resistivity (ρ), which is obtained by electroless plating, for example.

FIGS. 3A through 3D illustrate, in a sequence of process steps, an example of forming such a semiconductor device having copper interconnects. As shown in FIG. 3A, an insulating film (interlevel dielectric layer) 2, such as an oxide film of SiO₂ or a film of low-k material, is deposited on a conductive layer 1a on a semiconductor base 1 having formed semiconductor devices. Via holes 3 and trenches 4 for interconnect recesses are formed in the insulating film 2 by the lithography/etching technique. Thereafter, a barrier layer 5 of TaN or the like is formed on the insulating film 2, and a seed layer 6 as an electric supply layer for electroplating is formed on the barrier layer 5 by sputtering or the like.

Then, as shown in FIG. 3B, copper plating is performed onto the surface of the substrate W to fill the via holes 3 and the trenches 4 of the substrate W with copper and, at the same time, deposit a copper film 7 on the insulating film 2. Thereafter, the barrier layer 5, the seed layer 6 and the copper film 7 on the insulating film 2 are removed by chemical mechanical polishing (CMP) so as to make the surface of the copper film 7 filled in the via holes 3 and the trenches 4, and the surface of the insulating film 2 lie substantially on the same plane. Interconnects (copper interconnects) 8 composed of the seed layer 6 and the copper film 7, as shown in FIG. 3C, is thus formed in the insulating film 2.

Then, as shown in FIG. 3D, electroless plating is performed onto the surface of the substrate W to form a protective film 9 of a Co alloy, a Ni alloy or the like on surfaces of interconnects 8 selectively, thereby covering and protecting the surfaces of interconnects 8 with the protective film 9.

There will be described a process of forming a protective film (cap material) 9 of, e.g., a COWP alloy film selectively on surfaces of (copper) interconnects 8 by using a conventional electroless plating method with reference to FIG. 4. First, a substrate W such as a semiconductor wafer, which has been carried out a CMP process to expose interconnect 8 (see FIG. 3C), is prepared. The substrate W is immersed, for example, in dilute sulfuric acid or dilute hydrochloric acid having an ordinary temperature for about one minute to remove impurities such as a metal oxide film on a surface of an insulating film 2 and CMP residues such as of copper to thereby perform pre-cleaning of the substrate W. After the surface of the substrate W is cleaned (rinsed) with a cleaning liquid such as pure water, the substrate W is immersed, for example, in a PdSO₄/H₂SO₄ mixed solution or PdCl₂/HCl mixed solution having an ordinary temperature for about one minute to adhere Pd as a catalyst to the surfaces of the interconnects 8 so as to activate exposed surfaces of the interconnects 8.

After the surface of the substrate W is cleaned (rinsed) with pure water or the like, the substrate W is immersed, for example, in a CoWP plating solution at the solution temperature of 80° C. for about 120 seconds to carry out electroless plating selectively on surfaces of the activated interconnects 8. Thereafter, the surface of the substrate W is cleaned (rinsed) with a cleaning liquid such as pure water. Thus, a protective film 9 made of a COWP alloy film is formed selectively on the exposed surfaces of the interconnects 8 so as to protect the interconnects 8, as shown in FIG. 3D.

Next, the substrate W is subjected to post-cleaning in order to enhance the selectivity of the protective film 9, while scrubbing the surface of the substrate W with a roll, for example, thereby scrub-cleaning the substrate. Thereafter, the surface of the substrate is rinsed with pure water and dried.

### SUMMARY OF THE INVENTION

For interconnects (copper interconnects) which have been formed by flattening a surface of a substrate by CMP (chemical mechanical polishing), it is common practice to protect surfaces of interconnects from corrosion, using a corrosion inhibitor such as BTA (benzotriazole), until the next film-forming step. Such a corrosion inhibitor partly combines with the interconnect metal to form a metal complex, thereby preventing corrosion of the interconnects. The corrosion inhibitor and/or the metal complex needs to be completely removed from the substrate surface right before the next film-forming step. If the next film-forming step is the formation of an insulating barrier layer on the substrate surface by CVD, then the corrosion inhibitor and/or the metal complex on the substrate surface can be removed by a dry processing, such as plasma cleaning or UV irradiation, which is carried out as a pre-processing.

On the other hand, in the case where the next film-forming step is electroless plating to form a protective film selectively on exposed surfaces of interconnects, the corrosion inhibitor and/or the metal complex on the surfaces of the interconnects, because of their generally strong adhesion to the interconnect surfaces, may not be fully removed by pre-cleaning (pre-processing) which comprises ejecting a processing liquid toward the substrate surface or immersing the substrate in a processing liquid. Thus, the corrosion inhibitor and/or the metal complex may remain on part of the interconnect surfaces after cleaning. The remaining substance adversely affects the next-step catalyst application processing and/or electroless plating, resulting in non-uniform thickness of a protective film formed by the electroless plating on the interconnect surfaces.

In the case of carrying out pre-cleaning (pre-processing) of a substrate by jetting a processing liquid toward a surface of the substrate, jetting the processing liquid from a large number of jet nozzles is generally practiced in order to effectively clean the entire substrate surface. A large amount of processing liquid (chemical) is therefore needed for one processing operation, which is disadvantageous in terms of cost. On the other hand, in the case of carrying out pre-cleaning (pre-processing) of a substrate by immersing the substrate in a processing liquid, the processing liquid is generally reused in a circulatory manner. There is therefore a case in which impurities, which have been mixed into the processing liquid, re-adhere to a surface of the substrate, lowering the cleaning efficiency. Further, this cleaning method generally requires a relatively long processing time.

In a process for forming, by electroless plating, a protective film selectively on exposed surfaces of embedded interconnects, it is required to secure the selectivity of the formation of the protective film so that a metal component will not remain on a surface of an insulating film, thereby preventing arise in leak current between interconnects. There are, however, cases where a particulate metal residue 10 having a diameter of the order of several nm to several tens of nm as shown in FIG. 5A, or a film-shaped metal residue 11 having a thickness of the order of several nm to ten and several nm as shown in FIG. 5B remains on a surface of an insulating film 2 after the formation, by electroless plating, of a protective film 9 on surfaces of interconnects 8.

As described above, in order to secure the selectivity of the formation of the protective film 9, the substrate is subjected to post-cleaning to remove the metal residues from the surface of the insulating film 2, as shown in FIG. 5C. The post-cleaning of the substrate is generally carried out by using a cylindrical long roll (roll sponge or roll brush), and roll-cleaning (post-cleaning) the substrate surface by rubbing with the roll the substrate surface wetted with a liquid chemical.

Though the cleaning (post-cleaning) with the roll is effective to remove the particulate metal residue 10 remaining on the insulating film 2, shown in FIG. 5A, the cleaning is not always effective for the film-shaped metal residue 13 remaining on the insulating film 2, shown in FIG. 5B.

In particular, when the pressure applied on the roll is low, the film-shaped metal residue 13 on the insulating film 2, which generally lies at a lower position than the surface of the protective film 9, often cannot be completely removed. Further, a dissolved portion of the protective film (alloy) 9 can re-adhere to the insulating film 2. When the pressure applied on the roll is made too high, on the other hand, a considerable amount of the protective film 9 formed on the interconnects 8 will be removed, whereby a necessary thickness of the protective film 9 will not be secured. In addition, it is generally difficult to equalize the relative speed between the surface of the rotating roll and the surface of the substrate over the entire substrate surface. Accordingly, the entire substrate surface cannot be cleaned uniformly, and a metal residue is likely to remain on part of the substrate surface.

The present invention has been made in view of the above situation. It is therefore a first object of the present invention to provide a substrate processing method and a substrate processing apparatus which can completely remove a corrosion inhibitor and/or a metal complex from a surface of a substrate prior to catalyst application processing and/or electroless plating, and can form a protective film having a uniform thickness on surfaces of interconnects.

It is a second object of the present invention to provide a substrate processing method and a substrate processing apparatus which can effectively remove metal residues, especially a film-shaped metal residue, remaining on an insulating film after the formation of a protective film for protecting interconnects.

In order to achieve the above first object, the present invention provides a substrate processing method comprising preparing a substrate having metal interconnects formed in an electric insulator, carrying out pre-processing of the substrate by bringing a cleaning member into contact with the front surface or both surfaces of the substrate in a wet state and moving them relative to each other while supplying a pre-processing liquid to the front surface or both surfaces of the substrate, and then forming a protective film selectively on surfaces of the metal interconnects by bringing the front surface of the substrate into contact with an electroless plating solution.

According to the present invention, when forming a protective film on surfaces of interconnects either directly without applying a catalyst to the interconnects or after carrying out cleaning of the surface of the substrate and processing to apply a catalyst to the surfaces of the interconnects simultaneously by using the same pre-processing liquid, a corrosion inhibitor and/or a metal complex remaining on the substrate surface can be completely removed, prior to the film formation by electroless plating, by the pre-processing using a combination of the chemical action of the pre-processing liquid and the mechanical action (scrub cleaning) of a cleaning member. The pre-processing can be carried out on the entire surface of the substrate by bringing the cleaning member into contact with the surface of the substrate and moving the cleaning member and the substrate relative to each other.

Preferably, the surface of the substrate after the pre-processing is rinsed with pure water, and the substrate surface is brought into contact with the electroless plating solution before the substrate surface becomes fully dry.

This can prevent the re-formation of an oxide film on surfaces of interconnects or the formation of watermarks during the period between the pre-processing and the initiation of electroless plating, thereby preventing the formation of defects in the protective film (plated film).

The present invention provides another substrate processing method comprising preparing a substrate having metal interconnects formed in an electric insulator, carrying out pre-cleaning of the substrate by bringing a cleaning member into contact with the front surface or both surfaces of the substrate in a wet state and moving them relative to each other while supplying a pre-cleaning liquid to the front surface or both surfaces of the substrate, applying a catalyst to surfaces of the metal interconnects by bringing the substrate surface after the pre-cleaning into contact with a catalyst application solution, and then forming a protective film selectively on the surfaces of the metal interconnects by bringing the front surface of the substrate into contact with an electroless plating solution

According to the present invention, when forming a protective film after applying a catalyst to surfaces of interconnects, a corrosion inhibitor and/or a metal complex remaining on the substrate surface can be completely removed, prior to the catalyst application, by pre-cleaning using a combination of the chemical action of a cleaning liquid and the mechanical action of a cleaning member. This makes it possible to apply the catalyst more uniformly to the surfaces of the interconnects and to form the protective film in the absence of a corrosion inhibitor and/or a metal complex on the surface of the interconnects.

Preferably, the surface of the substrate after the pre-cleaning is rinsed with pure water, and the substrate surface is brought into contact with the catalyst application solution before the substrate surface becomes fully dry.

This can prevent the re-formation of an oxide film on surfaces of interconnects and the formation of watermarks during the period between the pre-cleaning processing and the initiation of the catalyst application processing, making it possible to apply a catalyst uniformly to the surfaces of the interconnects and to prevent the formation of defects in the protective film (plated film) formed by the later electroless plating.

The present invention provides a substrate processing apparatus, comprising: a pre-processing unit for carrying out pre-processing of a substrate by bringing a cleaning member into contact with a front surface or both surfaces of the substrate in a wet state and moving them relative to each other while supplying a pre-processing liquid to the front surface or both surfaces of the substrate; and an electroless plating unit for forming a protective film selectively on surfaces of metal interconnects by bringing the front surface of the substrate into contact with an electroless plating solution.

The present invention provides another substrate processing apparatus, comprising: a pre-processing unit for carrying out pre-processing of a substrate by bringing a cleaning member into contact with a front surface or both surfaces of the substrate in a wet state and moving them relative to each other while supplying a pre-processing liquid to the front surface or both surfaces of the substrate; a catalyst application unit for applying a catalyst to surfaces of the metal interconnects by bringing the surface of the substrate after the pre-cleaning into contact with a catalyst application solution; and an electroless plating unit for forming a protective film selectively on the surfaces of the metal interconnects by bringing the front surface of the substrate into contact with an electroless plating solution.

In a preferred aspect of the present invention, the substrate processing apparatus further comprises a cleaning unit for cleaning the substrate by immersing the substrate in a cleaning liquid or by ejecting a cleaning liquid toward the substrate.

The substrate cleaning effect can be enhanced by carrying out multi-step processing using the combination of the pre-processing unit and the cleaning unit, or the combination of the pre-cleaning unit and the cleaning unit.

In a preferred aspect of the present invention, the cleaning member is formed of a porous polyvinyl alcohol having a continuous pore structure or a fluororesin.

A porous polyvinyl alcohol (PVA) having a continuous pore structure is excellent in hygroscopicity and chemical resistance and is widely used for a roll sponge. By using such a PVA roll sponge as a cleaning member to make contact with a surface of a substrate and clean the substrate surface, residues remaining on the substrate surface can be easily removed without damage to the substrate surface.

The cleaning member may also be a roll-shaped brush centrally having a rotating shaft.

A surface of a substrate can be cleaned with enhanced efficiency by cleaning the substrate surface by rotating a roll-shaped brush while keeping it in contact with the substrate surface.

In order to achieve the above second object, the present invention provides yet another substrate processing method comprising preparing a substrate having metal interconnects formed in an insulating film, forming a protective film selectively on exposed surfaces of the metal interconnects by electroless plating, carrying out post-cleaning of the substrate by spraying a post-cleaning liquid in a mist form toward substantially the entire surface of the substrate with the protective film selectively formed thereon, and rinsing with pure water the surface of the substrate after the post-cleaning and drying the substrate.

By carrying out cleaning (post-cleaning) of a substrate by spraying a post-cleaning liquid in a mist form toward a surface of the substrate, the kinetic energy of the cleaning liquid as well as its chemical energy can be utilized to effectively remove metal residues, including a film-shaped metal residue, remaining on an insulating film. In addition, re-adhesion of a dissolved portion of a protective film to the insulating film can be prevented. Further, by spraying the pre-cleaning liquid toward substantially the entire surface of the substrate, the entire surface can be cleaned more uniformly with the post-cleaning liquid. Unlike the case where such a type of nozzle that supplies a liquid linearly is employed, and a post-cleaning liquid is applied onto one point in a substrate surface and the liquid is allowed to flow over the substrate surface from the contact point by centrifugal force, according to the present invention the post-cleaning liquid sprayed in a mist form or as liquid droplets is directly applied onto the entire cleaning area of a substrate, whereby residues remaining on an insulating film can be effectively removed and the selectivity of electroless plating can be enhanced. This can also improve the leak current characteristics.

The present invention provides yet another substrate processing method comprising preparing a substrate having metal interconnects formed in an insulating film, forming a protective film selectively on exposed surfaces of the metal interconnects by electroless plating, carrying out first post-cleaning of the substrate by rubbing with a roll the surface of the substrate with the protective film selectively formed thereon, carrying out second post-cleaning of the substrate by spraying a post-cleaning liquid in a mist form toward substantially the entire surface of the substrate, and rinsing with pure water the surface of the substrate after the post-cleaning and drying the substrate surface.

According to the present method, a particulate metal residue remaining on an insulating film can be effectively removed mainly by the first post-cleaning, and a film-shaped metal residue remaining on the insulating film can be effectively removed mainly by the second post-cleaning. Since the first post-cleaning is to mainly remove a particulate metal residue remaining on an insulating film, it is possible to apply a low pressure on a roll, thereby preventing a protective film from being removed excessively by the first cleaning.

Preferably, the average particle diameter of the post-cleaning liquid sprayed in a mist form is 50 to 1000 μm, and the flow rate of the post-cleaning liquid is 0.5 to 10 L/min.

This can provide the post-cleaning liquid sprayed in a mist form with a kinetic energy necessary for effectively removing a film-shaped metal residue, etc. remaining on an insulating film.

Preferably, the post-cleaning liquid is sprayed in a form toward substantially the entire surface of the substrate from a position at a distance of 1 to 20 cm from the substrate while rotating the substrate at a rotational speed of 1 to 500 rpm.

This makes it possible to spray the post-cleaning liquid in a mist form more uniformly toward substantially the entire surface of the substrate.

In a preferred aspect of the present invention, the post-cleaning liquid is an organic acid containing a surfactant and having a pH of 2 to 5 or pure water having a pH of 6 to 8.

Thus, metal residues on an insulating film can be effectively removed by carrying out the cleaning processing generally for several tens of seconds, while the etching amount of the alloy film formed can be controlled up to several nm.

The post-cleaning liquid may also be an alkaline solution containing TMAH and having a pH of 7 to 12.

The present invention provides yet another substrate processing apparatus, comprising: a pre-processing unit for carrying out pre-plating processing of a surface of a substrate having metal interconnects formed in an insulating film; an electroless plating unit for forming a protective film selectively on exposed surfaces of the metal interconnects formed in the substrate surface which has undergone the pre-plating processing in the pre-processing unit; a spray-typepost-cleaning unit for post-cleaning the surface of the substrate with the protective film formed thereon by spraying a post-cleaning liquid in a mist form toward substantially the entire substrate surface; and a rinsing/drying unit for rinsing with pure water the surface of the substrate after the post-cleaning, and drying the substrate surface.

In the preferred aspect of the present invention, the spray-type post-cleaning unit includes a substrate holder for rotatably holding the substrate with its front surface facing downwardly, and a spray nozzle, disposed below the substrate holder, for spraying the post-cleaning liquid in a mist form toward the surface of the substrate in rotation.

In the preferred aspect of the present invention, the substrate processing apparatus further comprises a roll-type post-cleaning unit for cleaning the surface of the substrate with the protective film formed thereon by rubbing the substrate surface with a roll.

The present invention provides yet another substrate processing apparatus, comprising: a pre-processing unit for carrying out pre-plating processing of a surface of a substrate having metal interconnects formed in an insulating film; an electroless plating unit for forming a protective film selectively on exposed surfaces of the metal interconnects formed in the substrate surface which has undergone the pre-plating processing in the pre-processing unit; a post-cleaning unit for post-cleaning the surface of the substrate with the protective film formed thereon by rubbing the substrate surface with a roll, and post-cleaning the substrate surface by spraying a post-cleaning liquid in a mist form toward substantially the entire substrate surface; and a rinsing/drying unit for rinsing with pure water the surface of the substrate after the post-cleaning, and drying the substrate surface.

This can enhance cleaning efficiency without increasing a footprint of an apparatus.

In the preferred aspect of the present invention, the post-cleaning unit includes a substrate holder for rotatably holding the substrate, rolls movable closer to or away from a front and back surfaces of the substrate held by the substrate holder, and a spray nozzle for spraying the post-cleaning liquid in a mist form toward the surface of the substrate in rotation.

### BRIEF DESCRIPTION OF THE DRAWINGS

FIGS. 1A through 1C are diagrams illustrating a conventional damascene copper-interconnect structure;

FIGS. 2A through 2F are diagrams illustrating, in a sequence of process steps, a process for forming a protective film selectively on surfaces of interconnects by electroless plating;

FIGS. 3A through 3D are diagrams illustrating, in a sequence of process steps, a process for forming a protective film selectively on surfaces of interconnects by electroless plating;

FIG. 4 is a flow chart of a conventional process for forming a protective film selectively on surfaces of interconnects;

FIG. 5A is a schematic diagram illustrating a particulate metal residue remaining on a surface of an insulating film, FIG. 5B is a schematic diagram illustrating a film-shaped metal residue remaining on the surface of the insulating film, and FIG. 5C is a schematic diagram illustrating the insulating film after completely removing metal residues from the surface;

FIG. 6 is a layout plan view of a substrate processing apparatus according to an embodiment of the present invention;

FIG. 7 is a plan view of a pre-cleaning unit of the substrate processing apparatus shown in FIG. 6;

FIG. 8 is a schematic cross-sectional view of the pre-cleaning unit of the substrate processing apparatus shown in FIG. 6;

FIG. 9 is a front view of a catalyst application unit (depiction of an outer tank omitted) of the substrate processing apparatus shown in FIG. 6, showing the unit upon transfer of a substrate;

FIG. 10 is a front view of the catalyst application unit (depiction of an outer tank omitted) of the substrate processing apparatus shown in FIG. 6, showing the unit upon processing with a first processing liquid;

FIG. 11 is a front view of the catalyst application unit (depiction of an outer tank omitted) of the substrate processing apparatus shown in FIG. 6, showing the unit upon processing with a second processing liquid;

FIG. 12 is a cross-sectional view of a processing head of the catalyst application unit of the substrate processing apparatus shown in FIG. 6, showing the processing head upon transfer of a substrate;

FIG. 13 is an enlarged view of the portion A of FIG. 12;

FIG. 14 is a diagram corresponding to FIG. 13, showing the processing head of the catalyst application unit of the substrate processing apparatus shown in FIG. 6 upon setting of a substrate;

FIG. 15 is a diagram showing the system of the catalyst application unit of the substrate processing apparatus shown in FIG. 6;

FIG. 16 is a cross-sectional view of a substrate head of an electroless plating unit of the substrate processing apparatus shown in FIG. 6, showing the substrate head upon transfer of a substrate;

FIG. 17 is an enlarged view of the portion B of FIG. 16;

FIG. 18 is a diagram corresponding to FIG. 17, showing the substrate head of the electroless plating unit of the substrate processing apparatus shown in FIG. 6 upon setting of a substrate;

FIG. 19 is a diagram corresponding to FIG. 17, showing the substrate head of the electroless plating unit of the substrate processing apparatus shown in FIG. 6 upon plating;

FIG. 20 is a front view, partly broken away, of a plating tank of the electroless plating unit of the substrate processing apparatus shown in FIG. 6, showing the plating tank when the plating tank cover is closed;

FIG. 21 is a cross-sectional view of a cleaning tank of the electroless plating unit of the substrate processing apparatus shown in FIG. 6;

FIG. 22 is a diagram showing the system of the electroless plating unit of the substrate processing apparatus shown in FIG. 6;

FIG. 23 is a vertical sectional front view of a drying unit of the substrate processing apparatus shown in FIG. 6;

FIG. 24 is a flow chart of a process as carried out in the substrate processing apparatus shown in FIG. 6;

FIG. 25 is a layout plan view of a substrate processing apparatus according to another embodiment of the present invention;

FIG. 26 is a flow chart of a process as carried out in the substrate processing apparatus shown in FIG. 25;

FIG. 27 is a flow chart of another process as carried out in the substrate processing apparatus shown in FIG. 25;

FIG. 28 is a graph showing the distributions of leak current in interconnects in the samples of Example 3 and Comp. Examples 5 and 6;

FIG. 29 is a layout plan view of a substrate processing apparatus according to yet another embodiment of the present invention;

FIG. 30 is a schematic view of a roll-type post-cleaning unit of the substrate processing apparatus shown in FIG. 29;

FIG. 31 is a schematic view of a spray-type post-cleaning unit of the substrate processing apparatus shown in FIG. 29;

FIG. 32 is a flow chart of a process for processing of a substrate as carried out by the substrate processing apparatus shown in FIG. 29;

FIG. 33 is a flow chart of another process for processing of a substrate;

FIG. 34 is a schematic view of another spray-type post-cleaning unit;

FIG. 35 is a layout plan view of a substrate processing apparatus according to yet another embodiment of the present invention;

FIG. 36 is a schematic view of a post-cleaning unit of the substrate processing apparatus shown in FIG. 35, showing the unit upon cleaning of a substrate by means of rolls;

FIG. 37 is a schematic view of the post-cleaning unit of the substrate processing apparatus shown in FIG. 35, showing the unit upon cleaning of a substrate by spraying;

FIG. 38 is a schematic view of another post-cleaning unit, showing the unit upon cleaning of a substrate by means of rolls;

FIG. 39 is a schematic view of the post-cleaning unit shown in FIG. 38, showing the unit upon cleaning of a substrate by spraying; and

FIG. 40 is a graph showing the results of measurement of leak current between interconnects for the processed wafers of Examples 4 and 5 and Comp. Examples 7 and 8.

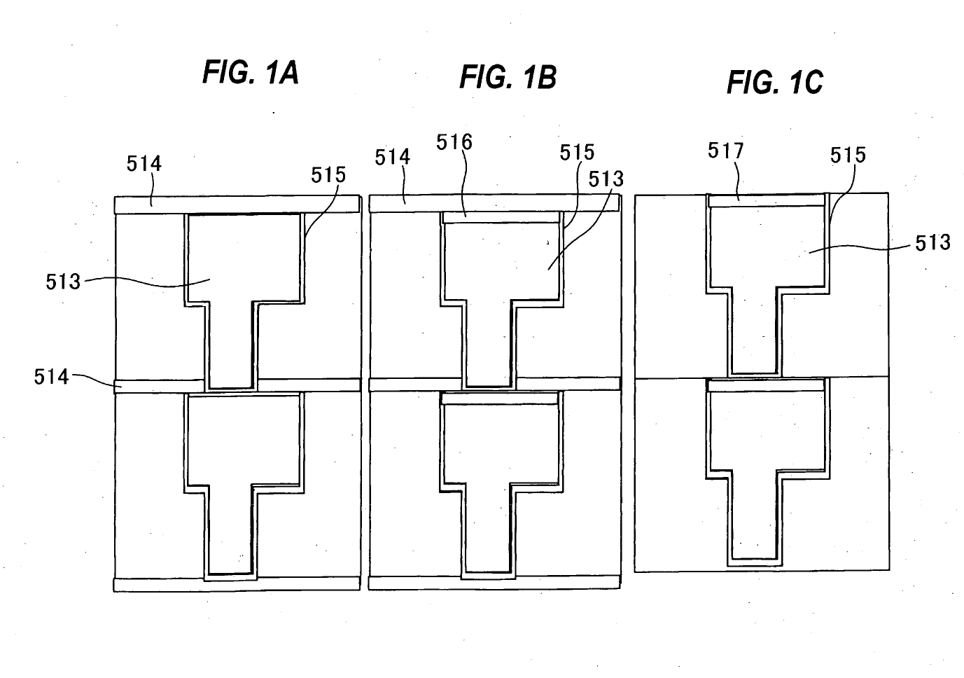

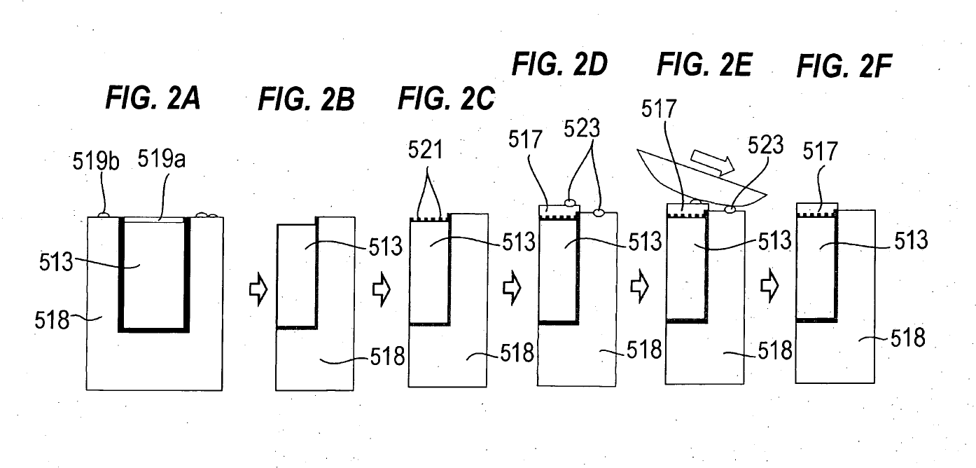

### DETAILED DESCRIPTION OF THE PREFERRED EMBODIMENTS

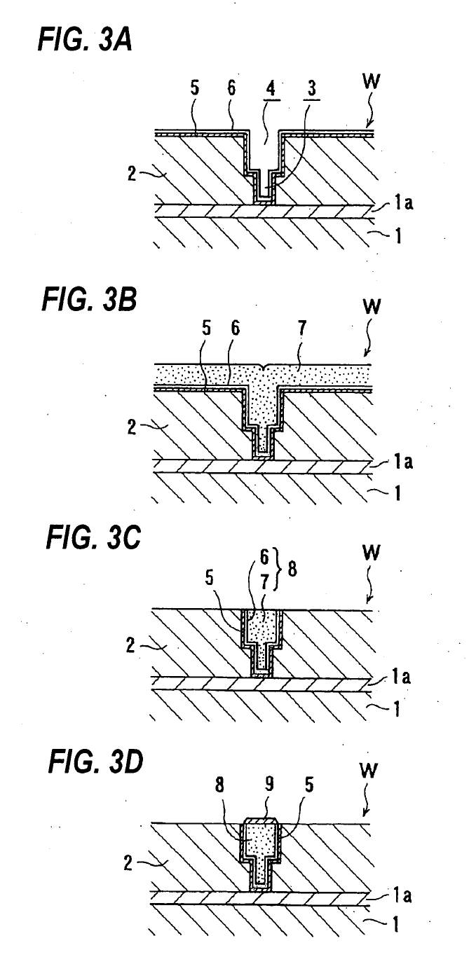

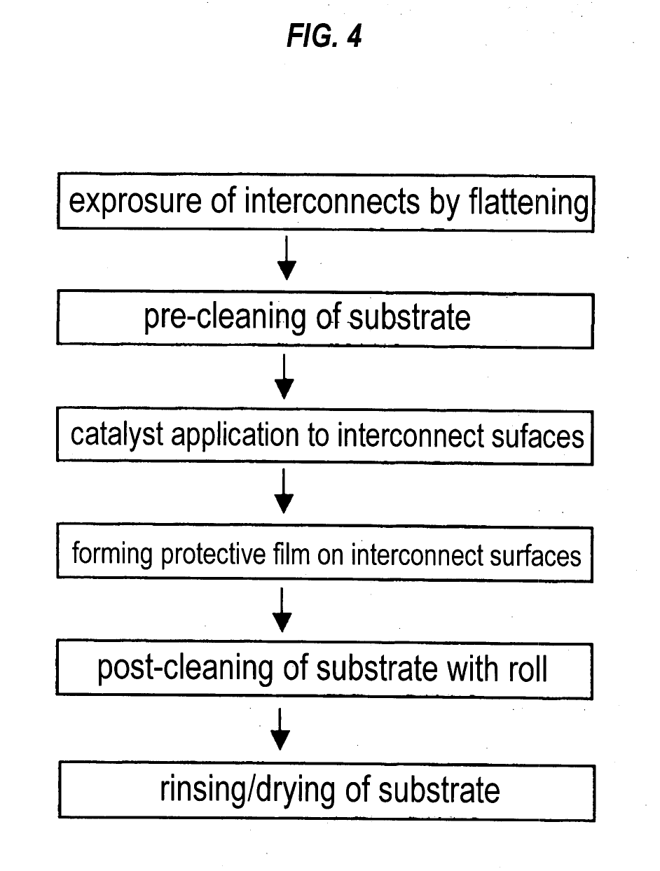

An embodiment of the present invention will now be described with reference to the drawings. The following description illustrates a case of selectively covering exposed surfaces of interconnects 8 with a protective film (cap material) 9 of, e.g., a CoWP alloy to protect interconnects 8, as shown in FIG. 3D.

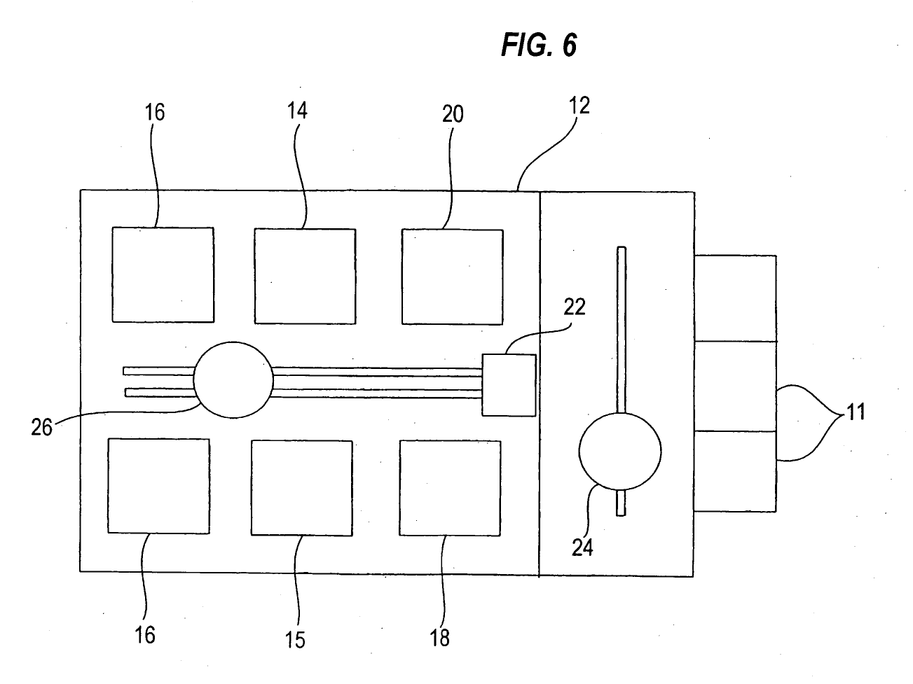

FIG. 6 is a layout plan view of a substrate processing apparatus according to an embodiment of the present invention. As shown in FIG. 6, the substrate processing apparatus is provided with loading/unloading units 11 each for mounting substrate cassette which accommodate a number of substrates W, such as semiconductor wafers, having interconnects 8 on their surfaces. Inside of a rectangular apparatus frame 12 having an air discharge system, there are disposed a pre-cleaning unit 14 for pre-cleaning a surface of the substrate W, and a catalyst application unit 15 for applying a catalyst, such as Pd, to surfaces of interconnects 8 by bringing a catalyst application solution into contact with the pre-cleaned surface of the substrate.

Inside of the apparatus frame 12, there are disposed two electroless plating units 16 each for performing electroless plating onto a surface of the substrate W, a post-cleaning unit 18 for performing post-cleaning (post-processing) of the substrate W to improve the selectivity of a protective film (metal film) 9 formed on surfaces of interconnects 8 by electroless plating, a drying unit 20 for drying the substrate W after the post-cleaning, and a temporary resting table 22. Furthermore, inside of the apparatus frame 12, there are disposed a movable first substrate transport robot 24 for transferring a substrate between the substrate cassette set in the loading/unloading unit 11 and the temporary resting table 22, and a moveable second substrate transport robot 26 for transferring a substrate between the temporary resting table 22 and each of the units 14, 15, 16, 18, and 20.

The respective units provided in the substrate processing apparatus shown in FIG. 6 will now be described in detail below. The pre-cleaning unit 14 is a unit adapted to remove a corrosion inhibitor and/or a metal complex, etc. remaining on the surface of the substrate W, including the surfaces of the interconnects, prior to catalyst application processing. The post-cleaning unit 18 is a unit adapted to remove particles and unnecessary substances on the substrate surface after electroless plating. In this embodiment, the pre-cleaning unit 14 and the post-cleaning unit 18 have the same construction, though different processing liquids are used. Therefore, a description will be herein made only of the pre-cleaning unit 14, and a description of the post-cleaning unit 18 will be omitted.

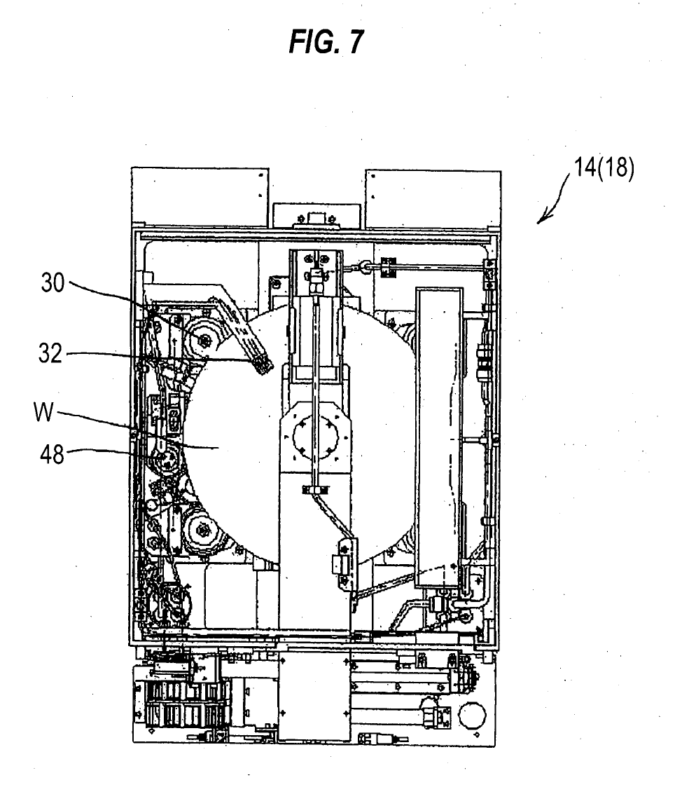

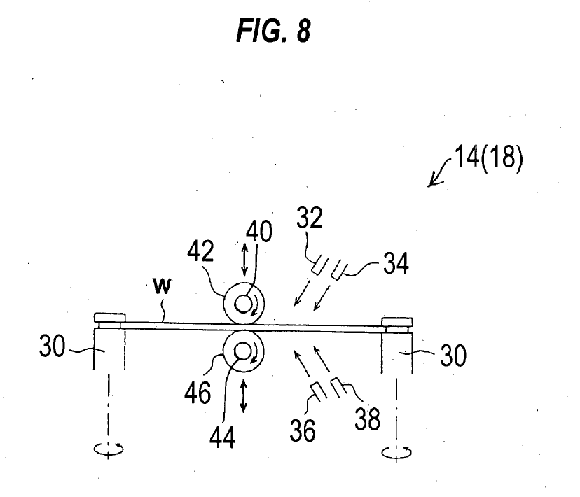

As shown in FIGS. 7 and 8, the pre-cleaning unit 14 includes a plurality of rollers 30 for holding the substrate W by pinching the peripheral end portion of the substrate W, a cleaning liquid nozzle 32 and a pure water nozzle 34 for supplying a cleaning liquid and pure water, respectively, to a front surface of the substrate W held by the rollers 30, and a cleaning liquid nozzle 36 and a pure water nozzle 38 for supplying a cleaning liquid and pure water, respectively, to a back surface of the substrate W held by the rollers 30.

A cylindrical cleaning member 42 centrally having a rotating shaft 40 and a cylindrical cleaning member 46 centrally having a rotating shaft 44 are disposed on the front surface side and the back surface side, respectively, of the substrate W held by the rollers 30. The cleaning members 42, 46 are vertically movable so that they can make contact with the substrate W. The cleaning members 42, 46 are each comprised of, for example, a roll-shaped brush or roll sponge formed of porous polyvinyl alcohol (PVA) having a continuous pore structure. By using as the cleaning members (roll-shaped brushes) 42, 46 the roll sponge of porous polyvinyl alcohol (PVA) having a continuous pore structure, which is excellent in hygroscopicity and chemical resistance, and bringing the cleaning members 42, 46 into contact with the surfaces of the substrate W and moving them relative to each other, residues remaining on the substrate surfaces can be easily removed without damage to the substrate surfaces. Further, by cleaning the substrate surfaces by rotating the cleaning members 42, 46, which are the roll-shaped brushes centrally having the rotating shafts 40, 44, while keeping them in contact with the substrate surfaces, the substrate surfaces can be cleaned with enhanced cleaning efficiency.

The cleaning members may be formed of a fluororesin.

In operation of the pre-cleaning unit 14, while holding the substrate W with its front surface (surface tone processed) facing upwardly by the rollers 30 and rotating the substrate W at a predetermined rotational speed, e.g., 110 rpm, by the rollers 30, pure water is supplied drop wise from the pure water nozzle 34 to the front surface (upper surface) of the substrate W to wet the entire surface of the substrate W with pure water. Next, while rotating the cleaning member (roll-shaped brush) 42, disposed above the substrate W, at a predetermined rotational speed, e.g. 100 rpm, the cleaning member 42 is lowered so as to bring it into contact with the front surface of the substrate W. Simultaneously with the contact of the cleaning member (roll-shaped brush) 42 with the surface of the substrate W, the cleaning nozzle 32, disposed above the substrate W, begins to supply a cleaning liquid to the surface of the substrate W. In this manner, when forming a protective film after applying a catalyst to surfaces of interconnects, a corrosion inhibitor and/or a metal complex, etc. remaining on the surface of the substrate W can be completely removed, prior to the processing to apply the catalyst to the surfaces of interconnects, by the pre-cleaning using a combination of the chemical action of the cleaning liquid and the mechanical action (scrub cleaning) of the cleaning member 42.

In parallel with the pre-cleaning of the front surface (upper surface) of the substrate, pre-cleaning of the back surface (lower surface) of the substrate is carried out, as necessary. In particular, pure water is supplied from the pure water nozzle 38 to the back surface (lower surface) of the substrate W. While rotating the cleaning member (roll-shaped brush) 46, disposed below the substrate W, at a predetermined rotational speed, e.g., 100 rpm, the cleaning member 46 is raised to bring it into contact with the back surface of the substrate W. Simultaneously with the contact of the cleaning member (roll-shaped brush) 46 with the back surface of the substrate W, the cleaning nozzle 36, disposed below the substrate W, begins to supply a cleaning liquid to the surface of the substrate W. The back surface of the substrate W is thus cleaned by the pre-cleaning using a combination of the chemical action of the cleaning liquid and the mechanical action of the cleaning member 46.

After cleaning the front surface of the substrate for a predetermined time, e.g., 30 seconds, the cleaning member 42 is raised off the surface of the substrate W, and the supply of the cleaning liquid from the cleaning liquid nozzle 32 is stopped. Thereafter, the surface of the substrate W is rinsed with pure water by supplying pure water from the pure water nozzle 34 to the front surface of the substrate W.

Similarly, after cleaning the back surface of the substrate for a predetermined time, the cleaning member 46 is lowered off the back surface of the substrate W, and the supply of the cleaning liquid from the cleaning liquid nozzle 36 is stopped. Thereafter, the back surface of the substrate W is rinsed with pure water by supplying pure water from the pure water nozzle 38 to the back surface of the substrate W.

It is also possible to provide only the pure water nozzle 38 on the back surface side of a substrate and carry out only rinsing of the back surface of the substrate with pure water. If there is no possibility of a cleaning liquid, supplied to the front surface of a substrate, flowing over to the back surface, rinsing of the back surface of the substrate with pure water may be omitted.

In this embodiment, the pre-cleaning unit 14 is also provided with a sponge 48 which rotates while keeping it in contact with the edge (peripheral end) of the substrate W, so that the edge of the substrate W can be scrub-cleaned by applying the sponge 48 to the edge.

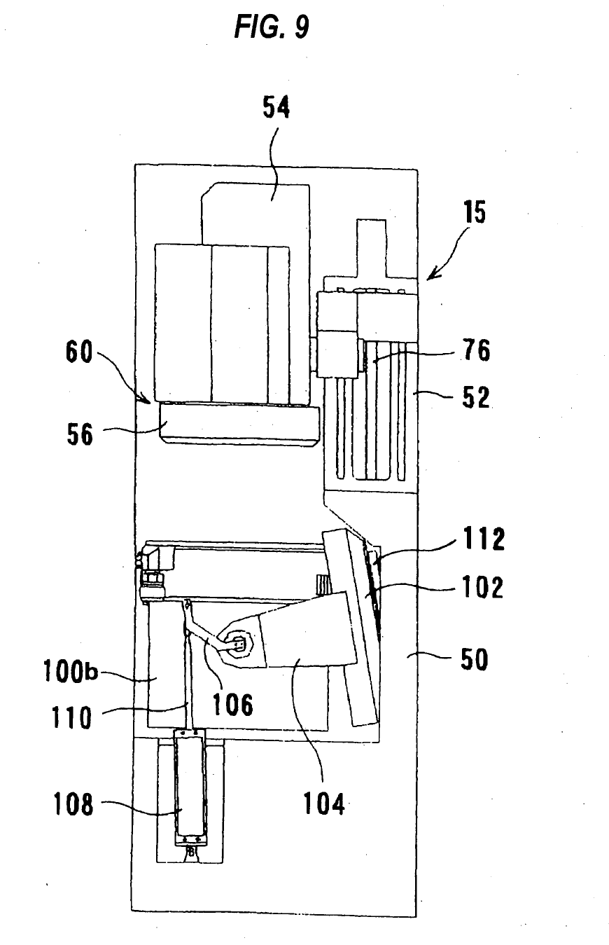

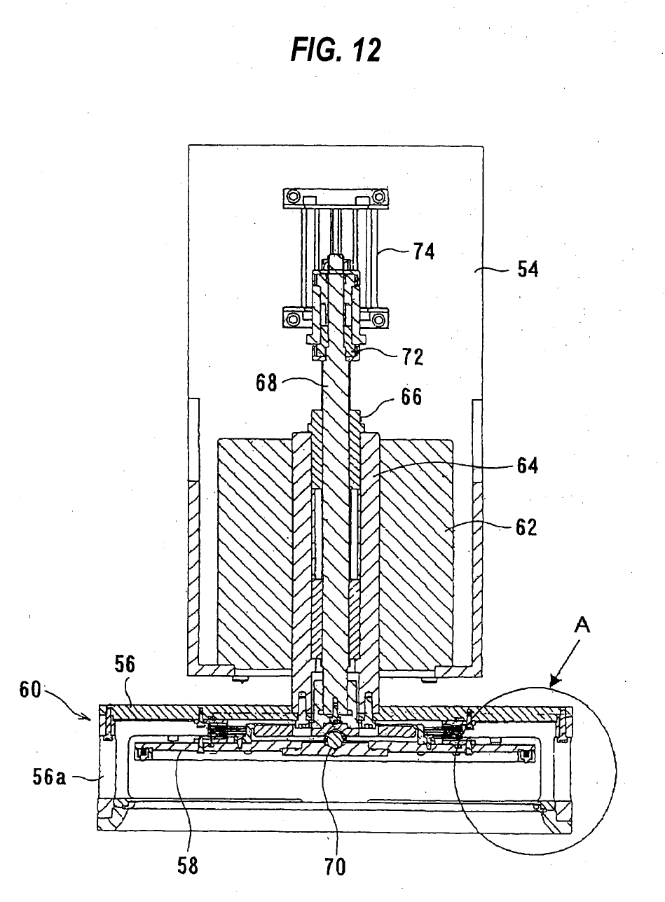

As shown in FIGS. 9 through 11, the catalyst application unit 15 includes a fixed frame 52 that is mounted on the upper part of a frame 50, and a movable frame 54 that moves up and down relative to the fixed frame 52. A processing head 60, which includes a bottomed cylindrical housing portion 56, opening downwardly, and a substrate holder 58, is suspended from and supported by the movable frame 54, as shown in FIG. 12. In particular, a head-rotating servomotor 62 is mounted to the movable frame 54, and the housing portion 56 of the processing head 60 is coupled to the lower end of the downward-extending output shaft (hollow shaft) 64 of the servomotor 62.

As shown in FIG. 12, a vertical shaft 68, which rotates together with the output shaft 64 via a spline 66, is inserted in the output shaft 64, and the substrate holder 58 of the processing head 60 is coupled to the lower end of the vertical shaft 68 via a ball joint 70. The substrate holder 58 is positioned within the housing portion 56. The upper end of the vertical shaft 68 is coupled via a bearing 72 and a bracket to a fixed ring-elevating cylinder 74 secured to the movable frame 54. Thus, by the actuation of the cylinder 74, the vertical shaft 68 moves vertically independently of the output shaft 64.

As shown in FIGS, 9 through 11, linear guides 76, which extend vertically and guide vertical movement of the movable frame 54, are mounted to the fixed frame 52, so that by the actuation of a head-elevating cylinder (not shown), the movable frame 54 moves vertically by the guide of the linear guides 76.

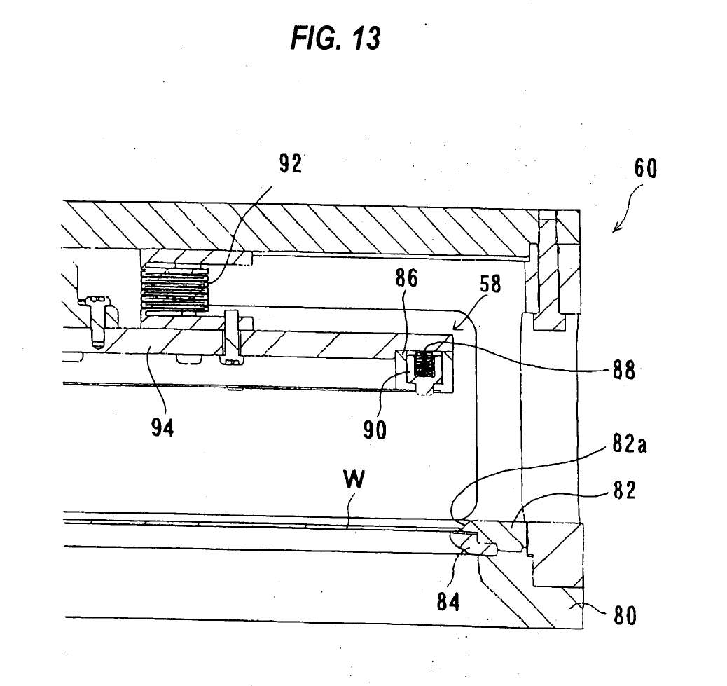

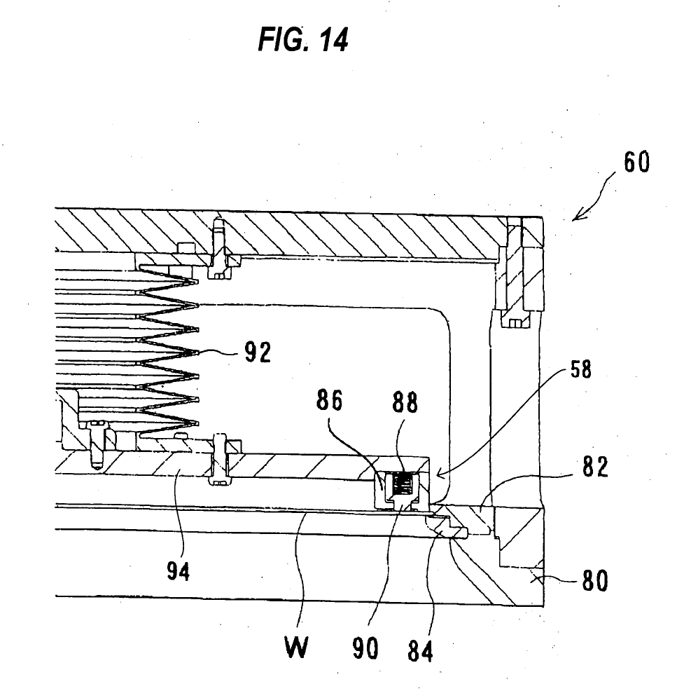

As shown in FIG. 12, substrate insertion windows 56a for inserting the substrate W into the housing portion 56 are formed in the circumferential wall of the housing portion 56 of the processing head 60. Further, as shown in FIGS. 13 and 14, a seal ring 84 is provided in the lower portion of the housing portion 56 of the processing head 60, an outer peripheral portion of the seal ring 84 being sandwiched between a main frame 80 made of, e.g., polyether ether ketone and a guide frame 82. The seal ring 84 is provided to make contact with a peripheral portion of the lower surface of the substrate W to seal the peripheral portion.

A substrate fixing ring 86 is fixed to a peripheral portion of the lower surface of the substrate holder 58. Columnar pushers 90 each protrudes downwardly from the lower surface of the substrate fixing ring 86 by the elastic force of a spring 88 disposed within the substrate fixing ring 86 of the substrate holder 58. Further, a flexible cylindrical bellows-like plate 92 made of, e.g., Teflon (registered trademark) is disposed between the upper surface of the substrate holder 58 and the upper wall of the housing portion 56 to hermetically seal therein. Further, the substrate holder 58 is provided with a covering plate 94 for covering an upper surface of the substrate held by the substrate holder 58.

When the substrate holder 58 is in a raised position, a substrate W is inserted through the substrate insertion window 56a into the housing portion 56. The substrate W is then guided by a tapered surface 82a provided in the inner circumferential surface of the guide frame 82, and positioned and placed at a predetermined position on the upper surface of the seal ring 84. In this state, the substrate holder 58 is lowered so as to bring the pushers 90 of the substrate fixing ring 86 into contact with the upper surface of the substrate W. The substrate holder 58 is further lowered so as to press the substrate W downwardly by the elastic forces of the springs 88, thereby forcing the seal ring 84 to make pressure contact with a peripheral portion of the front surface (lower surface) of the substrate W to seal the peripheral portion while nipping the substrate W between the housing portion 56 and the substrate holder 58 to hold the substrate W.

When the head-rotating servo motor 62 is driven while the substrate W is thus held by the substrate holder 58, the output shaft 64 and the vertical shaft 68 inserted in the output shaft 64 rotate together via the spline 66, whereby the substrate holder 58 rotates together with the housing portion 56.

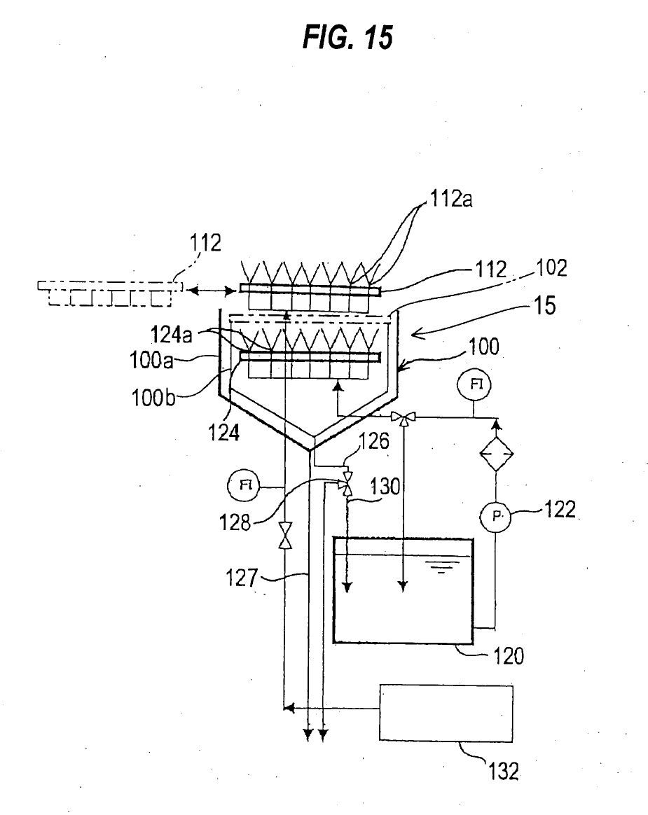

At a position below the processing head 60, there is provided an upward-open processing tank 100 (see FIG. 15) comprising an outer tank 100a and an inner tank 100b which have a slightly larger inner diameter than the outer diameter of the processing head 60. A pair of leg portions 104, which is mounted to a lid 102, is rotatably supported on the outer circumferential portion of the inner tank 100b. Further, as shown in FIGS. 9 through 11, a crank 106 is integrally coupled to each leg portion 106, and the free end of the crank 106 is rotatably coupled to the rod 110 of a lid-moving cylinder 108. Thus, by the actuation of the lid-moving cylinder 108, the lid 102 moves between a processing position at which the lid 102 covers the top opening of the inner tank 100b and a retreat position beside the inner tank 100b. In the surface (upper surface) of the lid 102, there is provided a nozzle plate 112 having a large number of ejection nozzles 112a for ejecting, e.g., pure water outwardly (upwardly).

Further, as shown in FIG. 15, a nozzle plate 124, having a plurality of ejection nozzles 124a for ejecting upwardly a processing liquid supplied from a first processing liquid tank 120 by driving a first processing liquid pump 122, is provided in the inner tank 100b of the processing tank 100 in such a manner that the ejection nozzles 124a are equally distributed over the entire surface of the cross section of the inner tank 100b. A drainpipe 126 for draining a first processing liquid (waste liquid) to the outside is connected to the bottom of the inner tank 100b. A three-way valve 128 is provided in the drainpipe 126 and the first processing liquid (waste liquid) is returned to the first processing liquid tank 120 through a return pipe 130 connected to one of outlet ports of the three-way valve 128 so as to reuse the first processing liquid (waste liquid), as needed.

The nozzle plate 112 mounted on the surface (upper surface) of the lid 102 is connected to a second processing liquid supply source 132. Thus, the second processing liquid is ejected toward the surface of the substrate from the ejection nozzles 112a. A drain pipe 127 is connected to the bottom of the outer tank 100a.

The processing head 60, which holds the substrate, is lowered until the processing head 60 covers the opening in the upper end of the inner tank 100b of the processing tank 100. Then, the first processing liquid is ejected from the ejection nozzles 124a of the nozzle plate 124 disposed in the inner tank 100b uniformly to the entire lower surface (surface to be processed) of the substrate W. The first processing liquid, which has been ejected, is prevented from being scattered around and is discharged outside through the drainpipe 126.

The processing head 60 is then elevated. With the opening in the upper end of the inner tank 100b being closed by the lid 102, the second processing liquid is ejected from the ejection nozzles 112a of the nozzle plate 112 disposed on the upper surface of the lid 102 to the substrate W held by the processing head 60, thereby ejecting uniformly to the entire lower surface (surface to be processed) of the substrate W. The second processing liquid flows downwardly through the gap between the outer tank 100a and the inner tank 100b and is discharged through the drainpipe 127. The second processing liquid is therefore prevented from flowing into the inner tank 100b and from being mixed with the first processing liquid.

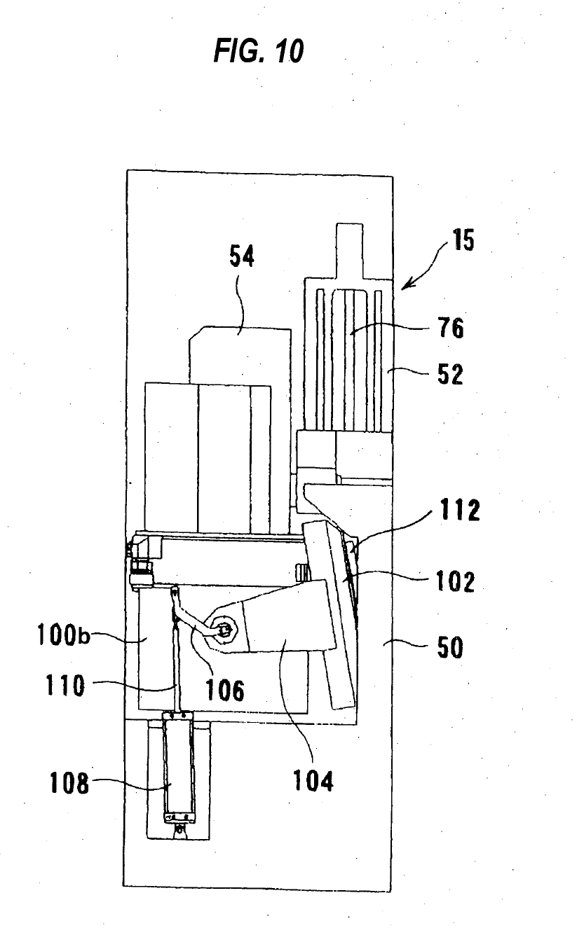

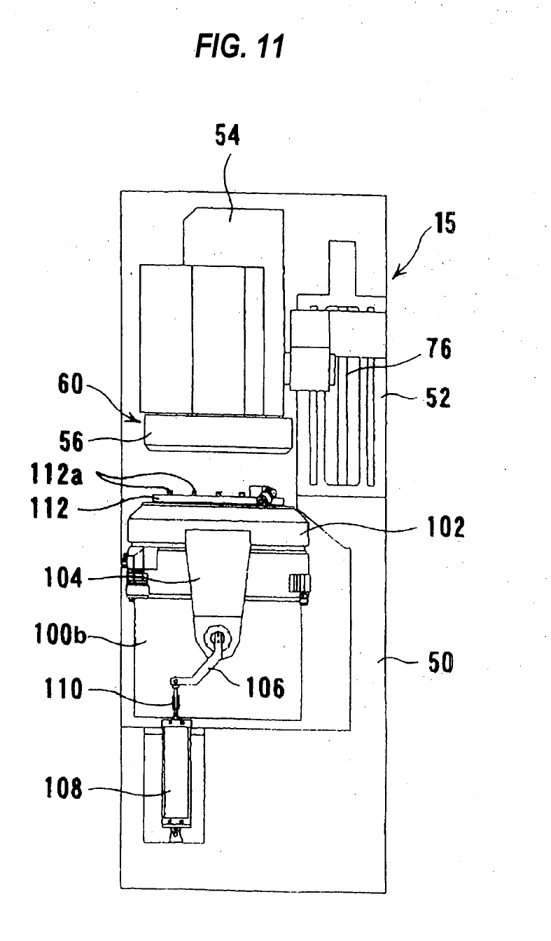

The catalyst application unit 15 operates as follows: When the processing head 60 is elevated, as shown in FIG. 9, the substrate W is inserted into the processing head 60 and held thereby. Thereafter, as shown in FIG. 10, the processing head 60 is lowered until it is positioned to cover the opening in the upper end of the inner tank 100b of the processing tank 100. Then, while the processing head 60 is being rotated to rotate the substrate W held thereby, the first processing liquid is ejected from the ejection nozzles 124a of the nozzle plate 124 disposed in the inner tank 100b of the processing tank 100 uniformly to the entire lower surface of the substrate W, as shown in FIG. 15. The processing head 60 is elevated to and stopped in a predetermined position, and, as shown in FIG. 11, the lid 102 is moved to a position in which it covers the opening in the upper end of the inner tank 100b of the processing tank 100. Then, the second processing liquid is ejected from the ejection nozzles 112a of the nozzle plate 112 disposed on the upper surface of the lid 102 to the substrate W held and rotated by the processing head 60. In this manner, the substrate W can be processed with the first processing liquid and the second processing liquid such that the first processing liquid and the second processing liquid are not mixed with each other.

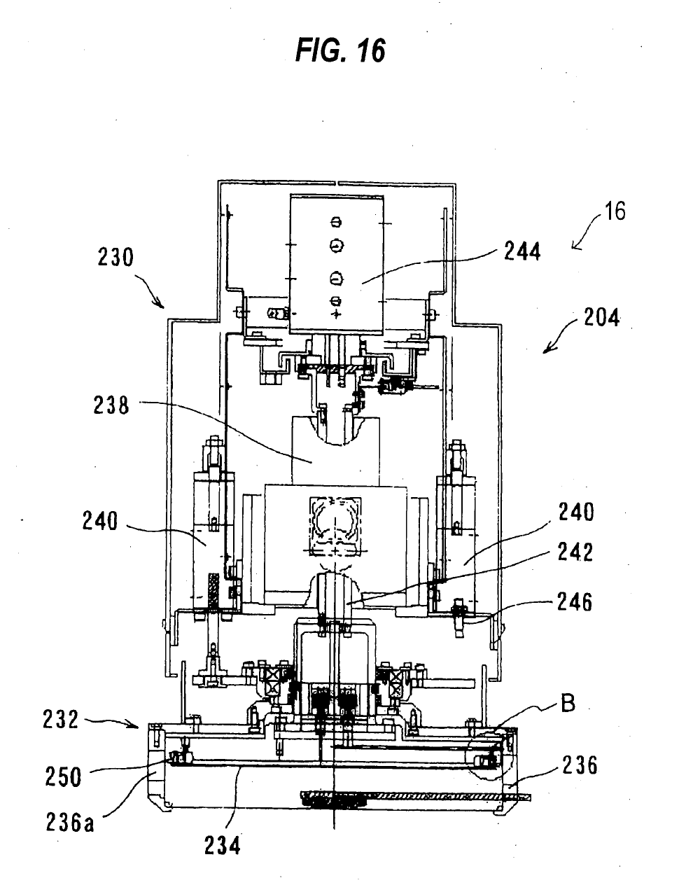

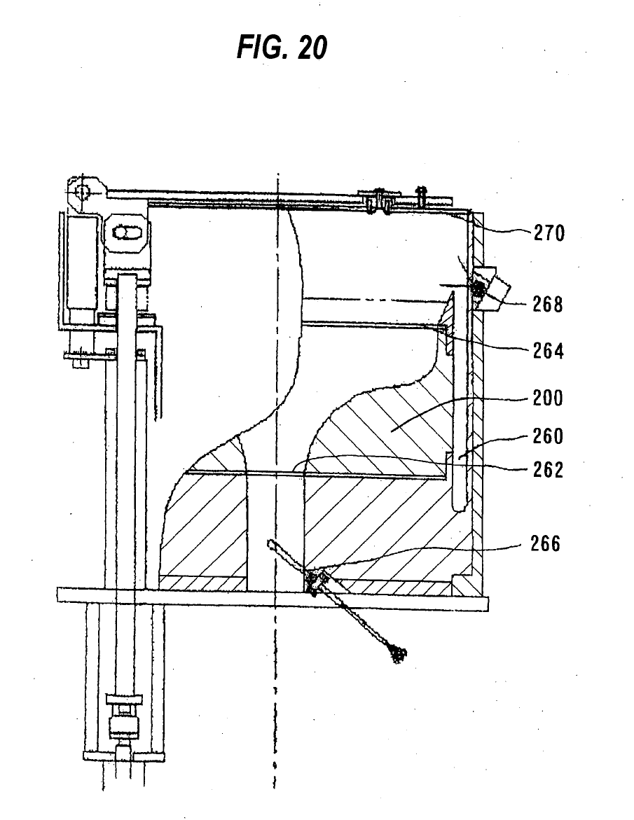

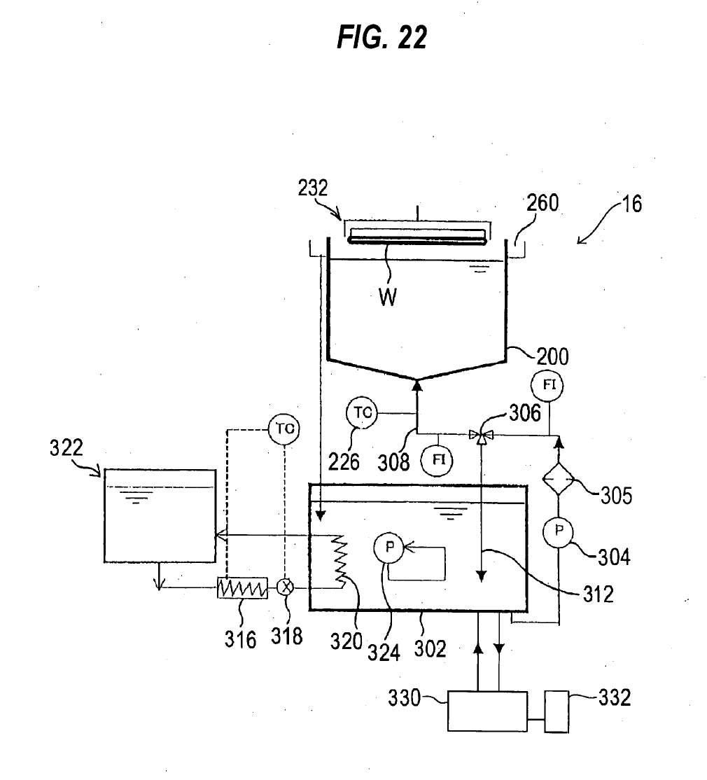

The electroless plating unit 16 is shown in FIGS. 16 through 22. The electroless plating unit 16 comprises a plating tank 200 (see FIGS. 20 and 22) and a substrate head 204, disposed above the plating tank 200, for holding the substrate W detachably.

As shown in detail in FIG. 16, the substrate head 204 comprises a housing portion 230 and a head portion 232. The head portion 232 mainly comprises a suction head 234 and a substrate receiver 236 disposed around the suction head 234. The housing portion 230 accommodates therein a substrate rotating motor 238 and substrate receiver driving cylinders 240. The substrate rotating motor 238 has a hollow output shaft 242 having an upper end coupled to a rotary joint 244 and a lower end coupled to the suction head 234. The substrate receiver driving cylinders 240 have respective rods coupled to the substrate receiver 236 of the head portion 232. Stoppers 246 for mechanically limiting the substrate receiver 236 against upward movement are disposed in the housing portion 230.

A splined structure is provided between the suction head 234 and the substrate receiver 236. The substrate receiver 236 is vertically moved relative to the suction head 234 by the actuation of the substrate receiver driving cylinders 240. When the substrate rotating motor 238 is driven to rotate the output shaft 242, the suction head 234 and the substrate receiver 236 are rotated in unison with the rotation of the output shaft 242.

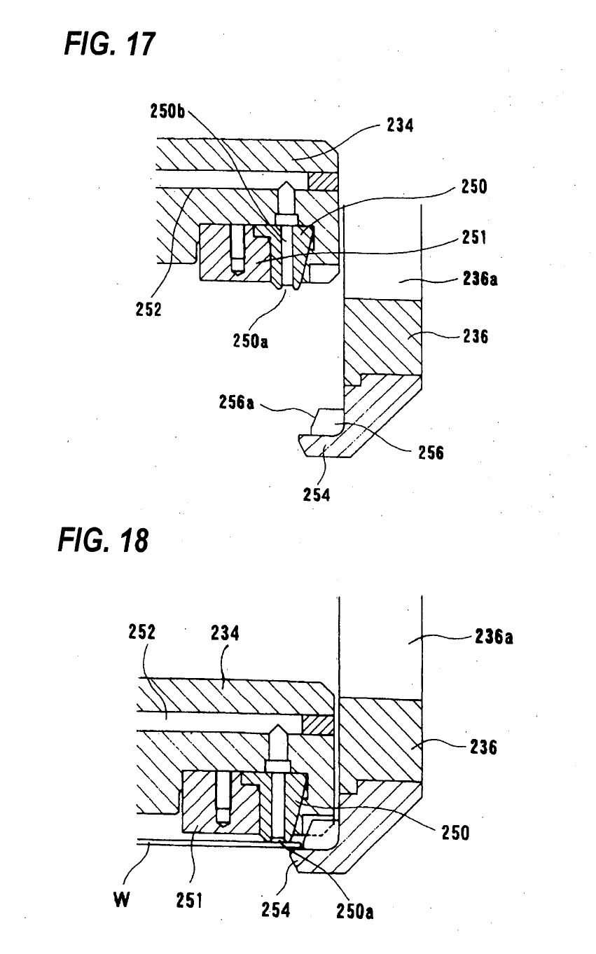

As shown in detail in FIGS. 17 through 19, a suction ring 250, for attracting and holding a substrate W against its lower surface to be sealed, is mounted on a lower circumferential edge of the suction head 234 by a presser ring 251. A recess 250a continuously defined in a lower surface of the suction ring 250 in a circumferential direction communicates with a vacuum line 252 extending inside of the suction head 234 via a communication hole 250b defined in the suction ring 250. By evacuating the recess 250a, the substrate W is attracted and held. Thus, the substrate W is attracted and held under vacuum along a (radially) narrow circumferential area. Accordingly, it is possible to minimize any adverse effects (flexing or the like) caused by the vacuum on the substrate W. Further, when the suction ring 250 is immersed in the electroless plating solution, all portions of the substrate W including not only the front face (lower surface) of the substrate W, but also its circumferential edge can be immersed in the electroless plating solution. The substrate W is released by supplying N₂ into the vacuum line 252.

Meanwhile, the substrate receiver 236 is in the form of a bottomed cylinder opened downward. Substrate insertion windows 236a for inserting the substrate W into the substrate receiver 236 are defined in a circumferential wall of the substrate receiver 236. A disk-like ledge 254 projecting inward is provided at a lower end of the substrate receiver 236. Protrusions 256, each having an inner tapered surface 256a for guiding the substrate W, are provided on an upper portion of the ledge 254.

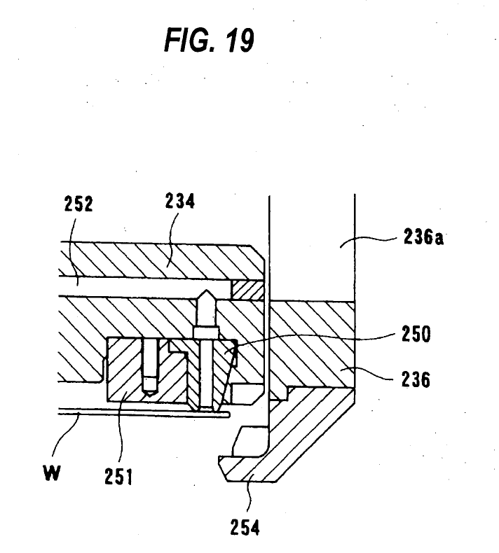

As shown in FIG. 17, when the substrate receiver 236 is in a lowered position, the substrate W is inserted through the substrate insertion window 236a into the substrate receiver 236. The substrate W is then guided by the tapered surfaces 256a of the protrusions 256 and positioned and placed at a predetermined position on an upper surface of the ledge 254. In this state, as shown in FIG. 18, the substrate receiver 236 is lifted up so as to bring the upper surface of the substrate W placed on the ledge 254 of the substrate receiver 236 into abutment against the suction ring 250 of the suction head 234. Then, the recess 250a in the vacuum ring 250 is evacuated through the vacuum line 252 to attract and hold the substrate W while sealing the upper peripheral edge of the substrate W against the lower surface of the suction ring 250. For performing an electroless plating process, as shown in FIG. 19, the substrate receiver 236 is lowered several millimeters to space the substrate W from the ledge 254 so that the substrate W is attracted and held only by the suction ring 250. Thus, it is possible to prevent the front face (lower surface) of the peripheral edge portion of the substrate W from not being plated because of the presence of the ledge 254.

FIG. 20 shows the details of the plating tank 200. The plating tank 200 is connected at the bottom to a plating solution supply pipe 308 (see FIG. 22) and is provided in the peripheral wall with a plating solution recovery gutter 260. In the plating tank 200, there are disposed two current plates 262, 264 for stabilizing the flow of an electroless plating solution flowing upward. A thermometer 266, for measuring the temperature of the electroless plating solution to be introduced into the plating tank 200, is disposed at the bottom of the plating tank 200. Further, on the outer surface of the peripheral wall of the plating tank 200 and at a position slightly higher than the liquid level of the electroless plating solution held in the plating tank 200, there is provided an ejection nozzle 268 for ejecting a stop liquid which is a neutral liquid having a pH of 6 to 7.5, for example, pure water, slightly upward with respect to a diametrical direction in the plating tank 200. After the electroless plating, the substrate W held by the head portion 232 is lifted up and stopped at a position slightly above the liquid level of the electroless plating solution. In this state, pure water (stop liquid) is ejected from the ejection nozzle 268 toward the substrate W to cool the substrate W immediately, thereby preventing progress of electroless plating by the electroless plating solution remaining on the substrate W.

A plating tank cover 270 is openably and closably placed in the opening in the upper end of the plating tank 200. While no plating process is being performed in the plating tank 200, e.g., while the electroless plating unit is idling, the plating tank cover 270 closes the opening in the upper end of the plating tank 200 to prevent the plating solution in the plating tank 200 from being evaporated and radiating its heat uselessly.

As shown in FIG. 22, the plating tank 200 is connected at the bottom to the plating solution supply pipe 308 extending from a plating solution reservoir tank 302 and having a plating solution supply pump 304, a filter 305 and a three-way valve 306. Further, the plating solution recovery gutter 260 is connected to a plating solution recovery pipe extending from the plating solution reservoir tank 302. Thus, during a plating process, an electroless plating solution is supplied from the bottom of the plating tank 200 into the plating tank 200, and an electroless plating solution, which has overflowed into the plating tank 200, is recovered to the plating solution reservoir tank 302 by the plating solution recovery gutter 260 through the plating solution recovery pipe. Thus, the electroless plating solution can be circulated. A plating solution return pipe 312 for returning the electroless plating solution to the plating solution reservoir tank 302 is connected to one of ports of the three-way valve 306. Accordingly, the electroless plating solution can be circulated even at the time of a standby for plating.

Particularly, in this embodiment, by controlling the plating solution supply pump 304, the flow rate of the electroless plating solution circulated at the time of a standby of plating or a plating process can be set individually. Specifically, an amount of the electroless plating solution circulated at the time of the standby of plating is set to be in a range of 2 to 20 L/min, for example, and an amount of the electroless plating solution circulated at the time of the plating process is set to be in a range of 0 to 10 L/min, for example. Thus, a large amount of the electroless plating solution circulated at the time of the standby of plating can be ensured so as to maintain the temperature of a plating bath in a cell to be constant, and the amount of the electroless plating solution circulated at the time of the plating process is reduced so as to deposit a protective film (plated film) having a more uniform thickness.

The thermometer 266 provided in the vicinity of the bottom of the plating tank 200 measures the temperature of the electroless plating solution to be introduced into the plating tank 200 and controls a heater 316 and a flow meter 318 both described below based on the measurement results.

In this embodiment, there are provided a heating device 322 for heating the electroless plating solution indirectly by a heat exchanger 320 provided in the electroless plating solution in the plating solution reservoir tank 302 and employing, as a heating medium, water that has been increased in temperature by a separate heater 316 and passed through the flow meter 318, and a stirring pump 324 for circulating the electroless plating solution in the plating solution reservoir tank 302 to stir the electroless plating solution. This is because the apparatus should be arranged so that the apparatus can cope with a case where the electroless plating solution is used at a high temperature (about 80° C.). This method can prevent an extremely delicate electroless plating solution from being mixed with foreign matter or the like, unlike an in-line heating method.

According to this embodiment, the electroless plating solution is set such that a temperature of the substrate is 70 to 90° C. during plating by bringing it into contact with the substrate W, and is controlled such that the range of variations in liquid temperature is within ±2° C.

The electroless plating unit 16 is also provided with a plating solution sampling portion 330 for sampling an electroless plating solution in the plating reservoir tank 302, and a plating solution component analyzing section 332 for analyzing composition of the sampled electroless plating solution held in the electroless plating unit 16 by an absorption metric method, a titration method, an electrochemical measurement, or the like. The plating solution component analyzing section 332 measures, for example, the concentration of Co ion by absorbance analysis, ion chromatography analysis, capillary electrophoresis analysis or chelatometry analysis.

In electroless plating, the plating rate is higher at a higher temperature of an electroless plating solution, and a plating reaction does not occur at a too low temperature. In view of this, the temperature of the electroless plating solution is generally 60 to 95° C., preferably 65 to 85° C., more preferably 70 to 75° C. It is basically desirable not to lower the temperature of the electroless plating solution after once raising the temperature, regardless of whether plating is actually being carried out or not, and to keep the electroless plating solution at a temperature of not less than 55° C.

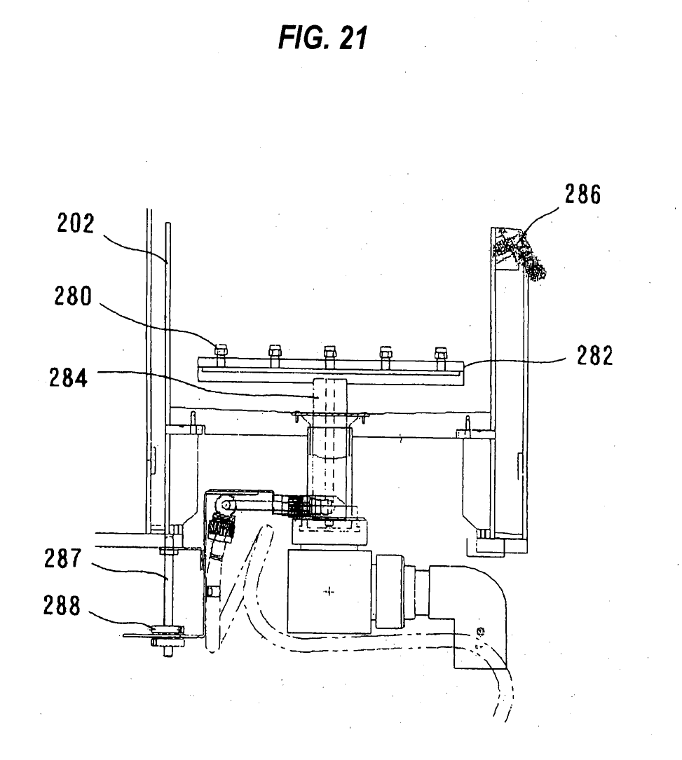

FIG. 21 shows the details of a cleaning tank 202 provided beside the plating tank 200. At the bottom of the cleaning tank 202, there is provided a nozzle plate 282 onto which a plurality of ejection nozzles 280 for ejecting a rinsing liquid, such as pure water, upward are attached. The nozzle plate 282 is coupled to an upper end of a nozzle vertical shaft 284. The nozzle vertical shaft 284 can be moved vertically by changing positions of engagement between a nozzle position adjustment screw 287 and a nut 288 engaging the screw 287 so as to optimize a distance between the ejection nozzles 280 and the substrate W disposed above the ejection nozzles 280.

Further, on the outer surface of the peripheral wall of the cleaning tank 202 and at a position higher than the ejection nozzles 280, there is provided a head cleaning nozzle 286 for ejecting a cleaning liquid, such as pure water, slightly downward with respect to a diametric direction in the cleaning tank 202 to blow the cleaning liquid to at least a portion of the head portion 232 of the substrate head 204 which is brought into contact with the plating solution.

In the cleaning tank 202, the substrate W held by the head portion 232 of the substrate head 204 is located at a predetermined position in the cleaning tank 202. A cleaning liquid (rinsing liquid) such as pure water is ejected from the ejection nozzles 280 to clean (rinse) the substrate W. At that time, a cleaning liquid such as pure water is ejected from the head cleaning nozzle 286 to clean, with the cleaning liquid, at least a portion of the head portion 232 of the substrate head 204 which is brought into contact with the electroless plating solution, thereby preventing a deposit from accumulating on a portion which is immersed in the electroless plating solution.

In the operation of the electroless plating unit 16, the substrate W is attracted and held by the head portion 232 of the substrate head 204, which is in the raised position, in the manner described above, and the electroless plating solution in the plating tank 200 is allowed to circulate.

When carrying out plating, the plating tank cover 270 of the plating tank 200 is opened, and the substrate head 204 is lowered while rotating it to immerse the substrate W, held by the head portion 232, in the electroless plating solution in the plating tank 200.

After keeping the substrate W immersed in the plating solution for a predetermined time, the substrate head 204 is raised to pull up the substrate W from the electroless plating solution in the plating tank 200 and, according to necessity, pure water (stop liquid) is ejected from the ejection nozzle 268 toward the substrate W to rapidly cool the substrate W, as described above. The substrate head 204 is further raised to move the substrate W to a position above the plating tank 200, and the rotation of the substrate head 204 is stopped.

Next, the substrate head 204 is moved to a position right above the cleaning tank 202 while keeping the substrate W attracted and held by the head portion 232 of the substrate head 204. Thereafter, while rotating the substrate head 204, the substrate head 204 is lowered to a predetermined position in the cleaning tank 202. A cleaning liquid (rinsing liquid), such as pure water, is ejected from the ejection nozzle 280 to clean (rinse) the substrate W and, at the same time, a cleaning liquid, such as pure water, is ejected from the head cleaning nozzle 286 to clean with the cleaning liquid at least those portions of the head portion 232 of the substrate head 204 which contact the electroless plating solution.

After completion of the cleaning of the substrate W, the rotation of the substrate head 204 is stopped, and the substrate head 204 is raised to pull up the substrate W to a position above the cleaning tank 202. The substrate head 204 is then moved to a transfer position where the substrate W is transferred to the second substrate transport robot 26, and the substrate W is sent to the next process step.

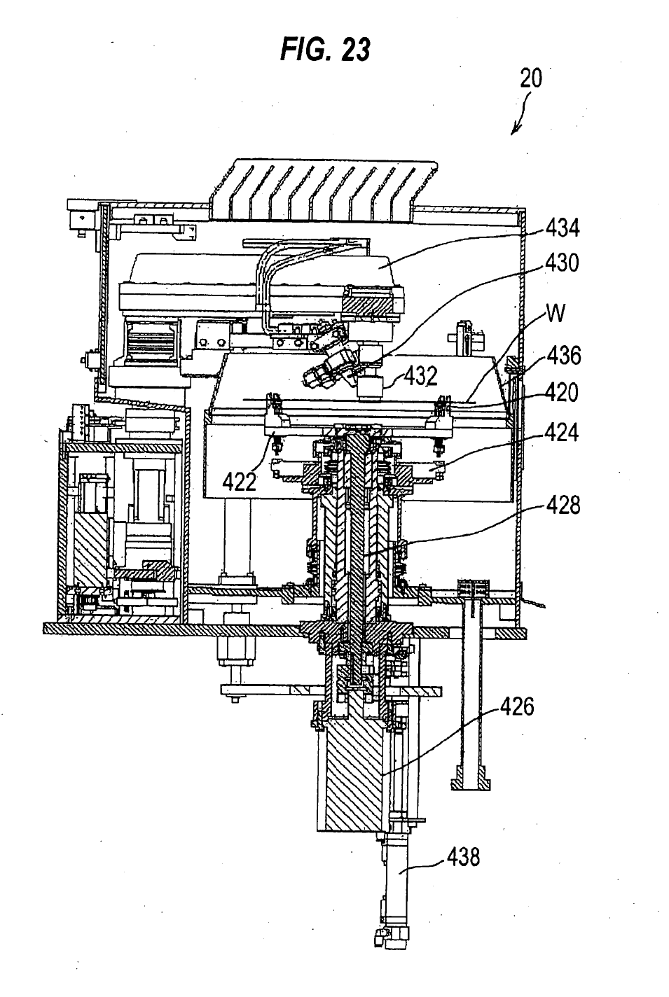

FIG. 23 shows the drying unit 20. The drying unit 20 is a unit for first carrying out chemical cleaning and pure water cleaning of the substrate W, and then fully drying the cleaned substrate W by spindle rotation, and includes a substrate stage 422 provided with a clamping mechanism 420 for clamping an edge portion of the substrate W, and a substrate attachment/detachment lifting plate 424 for opening/closing the clamping mechanism 420. The substrate stage 422 is coupled to the upper end of a spindle 428 that rotates at a high speed by the actuation of a spindle rotating motor 426.

Further, positioned on the side of the upper surface of the substrate W clamped by the clamping mechanism 420, there are provided a mega-jet nozzle 430 for supplying pure water to which ultrasonic waves from a ultrasonic oscillator have been transmitted during its passage through a special nozzle to increase the cleaning effect, and a rotatable pencil-type cleaning sponge 432, both mounted to the free end of a pivot arm 434. In operation, the substrate W is clamped by the clamping mechanism 420 and rotated, and the pivot arm 434 is pivoted while pure water is supplied from the mega-jet nozzle 430 to the cleaning sponge 432 and the cleaning sponge 432 is rubbed against the front surface of the substrate W, thereby cleaning the front surface of the substrate W. A cleaning nozzle (not shown) for supplying pure water is provided also on the side of the back surface of the substrate W, so that the back surface of the substrate W can also be cleaned with pure water sprayed from the cleaning nozzle.

The thus-cleaned substrate W is spin-dried by rotating the spindle 428 at a high speed.

A cleaning cup 436, surrounding the substrate W clamped by the clamping mechanism 420, is provided for preventing scattering of a cleaning liquid. The cleaning cup 436 is designed to move up and down by the actuation of a cleaning cup lifting cylinder 438.

It is also possible to provide the drying unit 20 with a cavi-jet function utilizing cavitation.

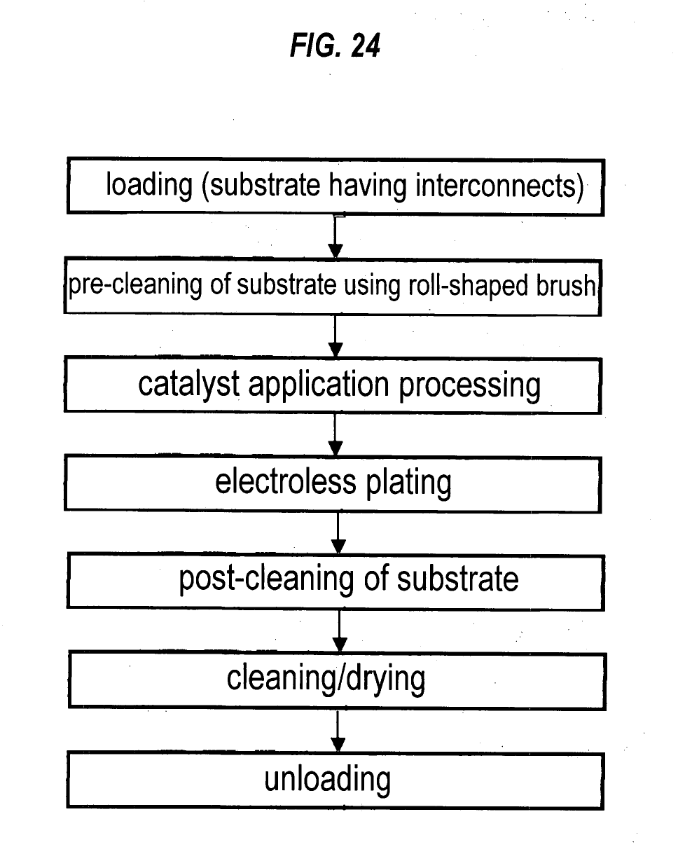

Next, a description will now be given of a series of substrate processings (electroless plating processings) as carried out by this substrate processing apparatus with reference to FIG. 24.

First, one substrate W is taken by the first substrate transport robot 24 out of a substrate cassette which is mounted in the loading/unloading unit 11 and in which substrates W, each having interconnects 8 formed in the surface, are housed with their front surfaces facing upwardly (face up), and the substrate W is transported to the temporary resting stage 22 and placed on it. The substrate W placed on the temporary resting stage 22 is transported by the second substrate transport robot 26 to the pre-cleaning unit 14.

The substrate W is held face up in the pre-cleaning unit 14 and subjected to pre-cleaning of the front surface using a combination of the chemical action of a cleaning liquid and the mechanical action (scrub cleaning) of the cleaning member to completely remove a corrosion inhibitor and/or a metal complex, etc. remaining on the substrate surface. In this embodiment, an organic acid solution, in particular an aqueous citric acid solution containing ethylenediamine diacetic acid (EDTA) and having a pH of more than 3 (pH>3), is used as a cleaning liquid in order to remove a corrosion inhibitor such as BTA (benzotriazole) and/or a metal complex.

In particular, the cleaning member (roll-shaped brush) 42 is rotated and brought into contact with the front surface, entirely wetted with pure water, of the rotating substrate W. Simultaneously with the contact of the cleaning member (roll-shaped brush) 42 with the surface of the substrate W, the cleaning liquid nozzle 32 disposed above the substrate W begins to supply the cleaning liquid, the aqueous citric acid solution containing ethylenediamine diacetic acid (EDTA) and having a pH of more than 3 (pH>3), to the surface of the substrate W. A corrosion inhibitor and/or a metal complex, etc. remaining on the surface of the substrate W is thus completely removed by the pre-cleaning using a combination of the chemical action of the cleaning liquid and the mechanical action of the cleaning member 42. If necessary, in parallel with the pre-cleaning of the front surface (upper surface) of the substrate, pre-cleaning of the back surface (lower surface) of the substrate is carried out.

After carrying out the above processing for a predetermined time, e.g., 30 seconds, the front surface of the substrate W is rinsed with pure water supplied from the pure water nozzle 38 and, if necessary, the back surface of the substrate W is also rinsed with pure water supplied from the pure water nozzle 38.

Next, the substrate after the pre-cleaning is transported to the catalyst application unit 15. In the catalyst application unit 15, the substrate W is held face down by the substrate holder 58, and catalyst is applied to the surfaces of the interconnects 8 by bringing, e.g., a Pd catalyst application solution to the front surface of the substrate. In particular, as shown in FIG. 10, the processing head 60 is located at a position where the processing head 60 covers the top opening of the inner tank 100b, and the first processing liquid in the first processing liquid tank 120 is ejected toward the substrate W from the ejection nozzles 112a of the nozzle plate 112 disposed in the inner tank 100b. A Pd catalyst application solution, for example, is used as the first processing liquid to apply the catalyst to the surfaces of the interconnects 8. Though any element of the platinum group, cobalt or nickel may used as a catalyst metal, it is preferred to use Pd as a catalyst from the viewpoints of reaction rate, easy control, etc.

It is preferred that after rinsing with pure water the surface of the substrate after the pre-cleaning, the substrate surface be brought into contact with the catalyst application solution before the substrate surface becomes fully dry. This can prevent the re-formation of an oxide film on the surfaces of interconnects and the formation of watermarks during the period between the pre-cleaning processing and the initiation of the catalyst application processing, making it possible to apply the catalyst uniformly to the surfaces of the interconnects and to prevent the formation of defects in the protective film (plated film) formed by the later electroless plating.

After the catalyst, such as Pd, is applied to the surfaces of the interconnects 8 in the catalyst application unit 15, the surface of the substrate is cleaned (rinsed) with pure water. In particular, after the substrate holder 58 holding the substrate W is raised above the inner bath 100b and the top opening of the inner tank 100b is covered with the lid 102, the second processing liquid is ejected from the ejection nozzles 112a of the nozzle plate 112 formed on the lid 102 to the substrate W. Degassed pure water is preferably used as the second processing liquid, thereby cleaning (rinsing) the surface of the substrate with pure water.

After completion of the catalyst application process, the substrate W is transported to the electroless plating unit 16. Is the electroless plating unit 16, the substrate head 20 holding the substrate face down is lowered to immerse the substrate W in the electroless plating solution in the plating tank 200, thereby carrying out electroless plating (electroless CoWP cap plating). In particular, the substrates immersed, for example, in a plating solution at the solution temperature of 80° C. for about 120 seconds to carry out electroless plating (electroless COWP cap plating) selectively on surfaces of the activated interconnects 8.

After pulling up the substrate W from the liquid level of the plating solution, the stop liquid for plating, such as pure water, is ejected from the ejection nozzle 268 toward the substrate W to stop the electroless plating by replacing the plating liquid on the surface of the substrate with the stop liquid. Next, the substrate head 204 is positioned at a predetermined position in the cleaning tank 202, and pure water is ejected from the ejection nozzle 280 of the plating plate 282 disposed in the cleaning tank 202 to clean (rinse) the substrate W. At that time, pure water is ejected from the head cleaning nozzle 286 to the head portion 232 to clean the head portion 232. Thus, a protective film 9 of a CoWP alloy film is formed selectively on surfaces of interconnects 8 to protect the interconnects 8.

Next, the substrate W after the electroless plating is transported by the second substrate transport robot 26 to the post-cleaning unit 18, where the substrate W is subjected to post-plating processing (post-cleaning) in order to enhance the selectivity of the protective film (alloy film) 9 formed on the surface of the substrate W and thereby increase the yield. In particular, while applying a physical force to the surface of the substrate W, for example, by roll scrub cleaning or pencil cleaning, a post-plating processing liquid (chemical solution) is supplied onto the surface of the substrate W to thereby completely remove plating residues, such as fine metal particles, from the insulating film (inter level dielectric layer) 2, thus enhancing the selectivity of plating.

The substrate W after the post-plating process is transported by the second substrate transport robot 26 to the drying unit 20, where the substrate W is rinsed, according to necessity, and then is rotated at a high speed to spin-dry the substrate W.

The spin-dried substrate W is placed by the second substrate transport robot 26 on the temporary resting stage 22, and the substrate W placed on the temporary resting stage 22 is returned by the first substrate transport robot 24 to the substrate cassette mounted in the loading/unloading unit 11.

According to this embodiment, when forming a protective film on surfaces of interconnects after applying a catalyst to the interconnects, a corrosion inhibitor and/or a metal complex remaining on the substrate surface can be completely removed, prior to the catalyst application, by the pre-cleaning using a combination of the chemical action of the cleaning liquid and the mechanical action of the cleaning member. This makes it possible to apply the catalyst more uniformly to the surfaces of the interconnects and to form the protective film in the absence of a corrosion inhibitor and/or a metal complex on the surfaces of the interconnects.

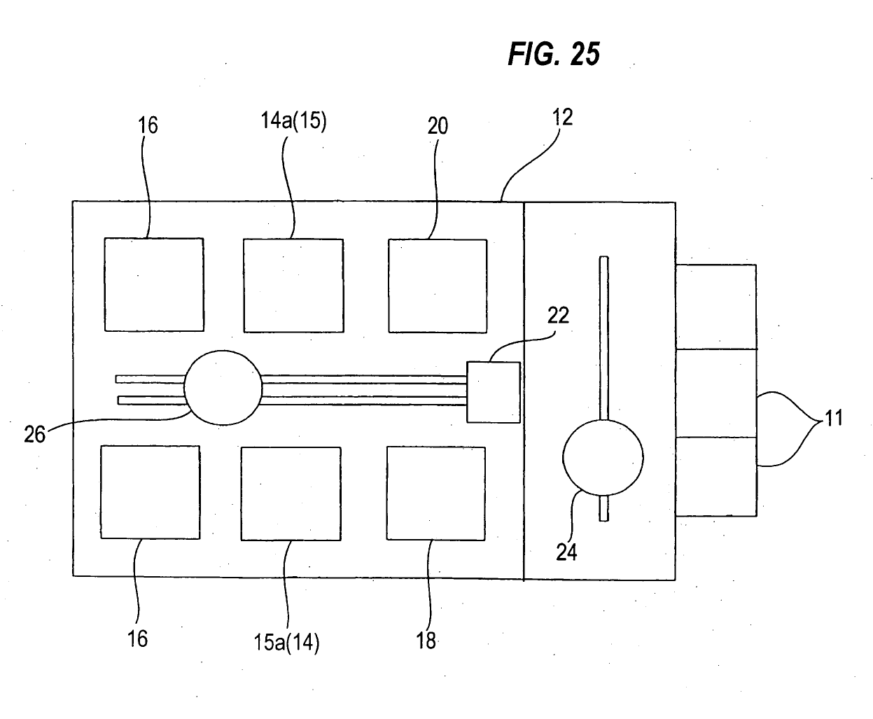

FIG. 25 shows a layout plan view of a substrate processing apparatus according to another embodiment of the present invention. The embodiment shown in FIG. 25 differs from the embodiment shown in FIG. 6 in that instead of the pre-cleaning unit 14 and the catalyst application unit 15 shown in FIG. 6, a cleaning unit 14a and a pre-processing unit 15a are disposed in the interior of the apparatus frame 12. The cleaning unit 14a has the same construction as the catalyst application unit 15 shown in FIG. 6, though the units use different processing liquids. The pre-processing unit 15a has the same construction as the pre-cleaning unit 14 shown in FIG. 6, though the units use different processing liquids.

In this embodiment, after cleaning a surface of a substrate in the cleaning unit 14a, cleaning of the surface of the substrate and application of a catalyst to surfaces of interconnects are carried out simultaneously, as pre-processing of the substrate, in the pre-processing unit 15a. Thereafter, a protective film is formed selectively on the surfaces of interconnects in the electroless plating unit 16.

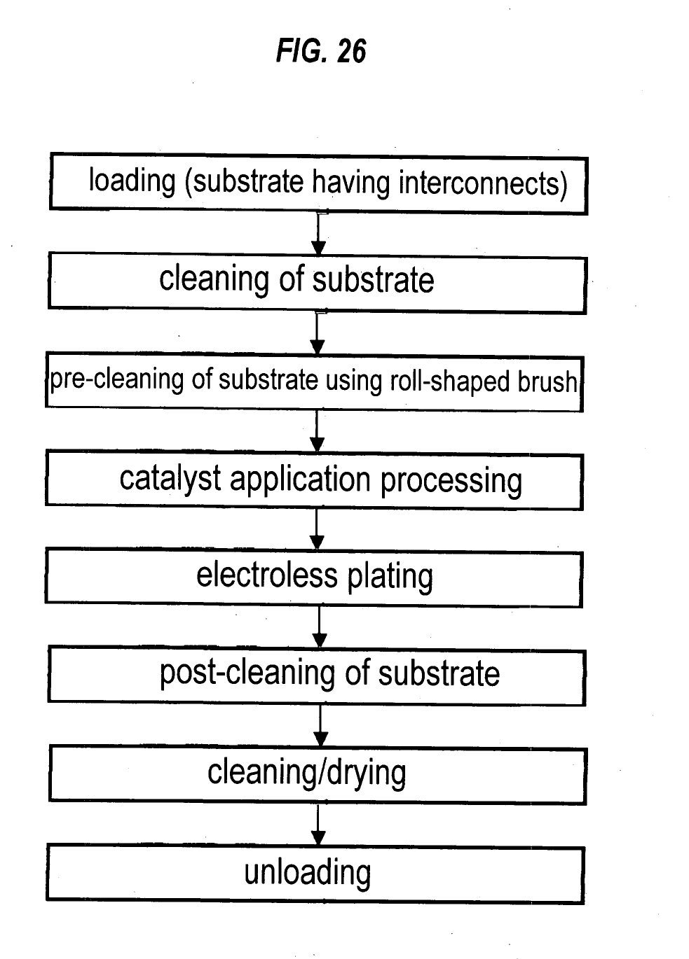

In particular, as shown in FIG. 26, one substrate W is taken by the first substrate transport robot 24 out of a substrate cassette having substrates housed therein, mounted in the loading/unloading unit 11, and the substrate W is transported to the temporary resting stage 22 and placed on it. The substrate W placed on the temporary resting stage 22 is transported by the second substrate transport robot 26 to the cleaning unit 14a.

In the cleaning unit 14a, using a cleaning liquid instead of the first processing liquid (catalyst application solution) used in the above-described catalyst application unit 15, the front surface of the substrate is cleaned with the cleaning liquid by jetting the cleaning liquid toward the surface of the substrate held face down, followed by rinsing with pure water of the front surface of the substrate. The substrate after the cleaning is transported to the pre-processing unit 15a.

In the pre-processing unit 15a, using a pre-processing liquid containing a catalyst (catalyst application/cleaning solution) instead of the cleaning liquid used in the above-described pre-cleaning unit 14, the front surface of the substrate W held face up is subjected to simultaneous processings of: catalyst application processing; and cleaning processing using a combination of the chemical action of the pre-processing liquid and the mechanical action (scrub cleaning) of the cleaning member, thereby completely removing a corrosion inhibitor and/or a metal complex, etc. remaining on the surface of the substrate and, at the same time, applying the catalyst to the surfaces of interconnects.

In particular, the cleaning member (roll-shaped brush) 42 (see FIG. 8) is rotated and brought into contact with the front surface, entirely wetted with pure water, of the rotating substrate W. Simultaneously with the contact of the cleaning member (roll-shaped brush) 42 with the surface of the substrate W, the cleaning liquid nozzle 32 (see FIG. 8) disposed above the substrate W begins to supply the pre-processing liquid (catalyst application/cleaning solution).

After carrying out the above simultaneous processings for a predetermined time, e.g., 30 seconds, the front surface of the substrate W is rinsed with pure water and, if necessary, the back surface of the substrate W is also rinsed with pure water.

It is preferred that after rinsing with pure water the surface of the substrate after the cleaning, the substrate surface be brought into contact with the pre-processing liquid before the substrate surfaces becomes fully dry. This can prevent the re-formation of an oxide film on the surfaces of interconnects and the formation of watermarks during the period between the cleaning processing and the initiation of the pre-processing, making it possible to apply a catalyst uniformly to the surfaces of the interconnects and to prevent the formation of defects in the protective film (plated film) formed by the later electroless plating.

Next, the substrate after the pre-processing is transported to the electroless plating unit 16, where selective electroless plating is carried out on surfaces of interconnects 8. The electroless plating and the subsequent process are carried out in the same manner as described above with reference to the preceding embodiment.

The effect of cleaning of a substrate can be enhanced by carrying out the multi-step processing using the combination of the cleaning unit 14a and the pre-processing unit 15a.

According to this embodiment, when forming a protective film on surfaces of interconnects after carrying out cleaning of the surface of the substrate and processing to apply a catalyst to the surfaces of the interconnects simultaneously by using the same pre-processing liquid, a corrosion inhibitor and/or a metal complex remaining on the substrate surface can be completely removed, prior to the film formation by electroless plating, by the pre-processing using a combination of the chemical action of the pre-processing liquid and the mechanical action (scrub cleaning) of the cleaning member. Further, the pre-processing can be carried out on the entire surface of the substrate by bringing the cleaning member into contact with the surface of the substrate and moving the cleaning member and the substrate relative to each other.

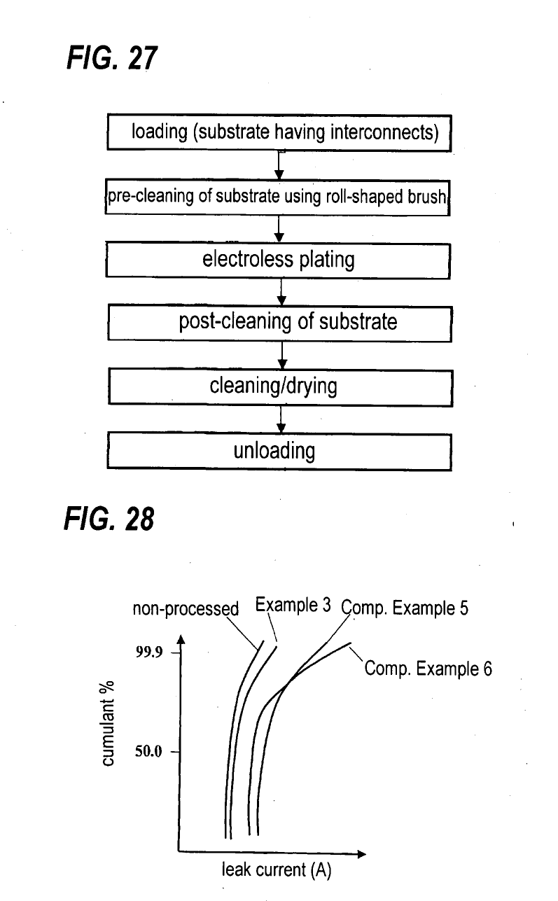

Depending on the type of an alloy of a protective film to be formed selectively on surfaces of interconnects, it is sometimes possible to form a protective film (alloy film) directly on a surface of a substrate without application of a catalyst. In the case of using such an alloy film as a protective film, a cleaning liquid of an organic acid solution, e.g., an aqueous citric acid solution containing ethylenediamine diacetic acid (EDTA) and having a pH of more than 3 (pH>3), as used in the above-described pre-cleaning unit 14, is used as a pre-processing liquid in the pre-processing unit 15a shown in FIG. 25. In operation, as shown in FIG. 27, a substrate W, which has been taken out of the substrate cassette mounted in the loading/unloading unit 11 and transported to the temporary resting stage 22, is transported to the pre-processing unit 15a. The substrate W is held face up in the pre-processing unit 15a and subjected to pre-cleaning of the front surface using a combination of the chemical action of the pre-processing liquid (cleaning liquid) and the mechanical action (scrub cleaning) of the cleaning member, thereby completely removing a corrosion inhibitor and/or a metal complex, etc. remaining on the surface of the substrate. Thereafter, a front surface of the substrate W is rinsed with pure water. If necessary, a back surface of the substrate W is also rinsed with pure water. The substrate W is then transported to the electroless plating unit 16 to carry out selective electroless plating on surfaces of interconnects 8. The electroless plating and the subsequent process are the same as in the preceding embodiment.

Also in this case, it is possible to carry out the pre-processing (cleaning) of the substrate in the pre-processing unit 15a after cleaning the substrate in the cleaning unit 14a.

In the above-described embodiments, pre-cleaning (pre-processing) of a substrate W is carried out by bringing the roll-shaped cleaning members 42, 46 into contact with the front surface or both surfaces of the substrate while rotating the cleaning members 42, 46 on the rotating shafts 40, 44 in the same direction and supplying a cleaning liquid (pre-processing liquid) to the front surface or both surfaces of the substrate W. However, it is possible to carry out pre-cleaning (pre-processing) of a substrate by bringing a rotatable cleaning member, mounted to a front end of a pivot arm, into contact with the substrate rotating horizontally while supplying a cleaning liquid (pre-processing liquid) to the front surface or both surfaces of the substrate. It is also possible to carry out pre-cleaning (pre-processing) of a substrate by bringing a rotatable cleaning member, mounted to a front end of a pivot arm, into contact with the substrate rotating horizontally while ejecting a liquid with ultrasonic vibration toward the surface of the substrate. Pre-cleaning (pre-processing) of a substrate may also be carried out by polishing the front surface or both surfaces of the substrate, e.g., with a buff.

### EXAMPLE 1

Pre-cleaning of a sample was carried out by using the pre-cleaning unit 14 shown in FIG. 6, and the cleaning effect was examined. First, a 300 mm across copper blanket wafer sample was prepared by forming a 1000 nm copper film uniformly over the surface by electroplating, followed by polishing of the copper film by CMP, leaving the copper film with a thickness of 500 nm. Benzotriazole (BTA) had been left on the copper surface of the sample after CMP.

The sample was held with its surface to be processed (front surface) facing upwardly by the rollers 30 of the pre-cleaning unit 14 and, while rotating the sample at 110 rpm, pure water was supplied to the surface for 5 seconds to wet the entire surface with pure water. Thereafter, while rotating the cleaning member (roll-shaped brush) 42 at 100 rpm, it was brought into contact with the surface of the sample. Simultaneously with the contact of the cleaning member 42 with the surface of the sample, the cleaning liquid nozzle 32 began to supply a cleaning liquid, an aqueous citric acid solution containing ethylenediamine diacetic acid (EDTA) and having a pH of more than 3 (pH>3), to the surface of the sample to carry out cleaning (pre-cleaning) of the sample. After carrying out the cleaning for 30 seconds, the sample was separated from the rollers 30 and, immediately thereafter, the surface of the sample was rinsed with pure water for 15 seconds.

### COMPARATIVE EXAMPLE 1

The same sample as used in Example 1 was prepared, and the sample was cleaned by a so-called spray method. In particular, the sample was set with its surface to be processed (front surface) facing downwardly in a spray-type cleaning unit. While horizontally rotating the sample at 20 rpm, a cleaning liquid, an aqueous citric acid solution containing ethylenediamine diacetic acid (EDTA) and having a pH of more than 3 (pH>3), was sprayed from a plurality of spray nozzles, disposed below the sample, toward the entire surface of the sample to carry out cleaning (pre-cleaning) of the sample. After carrying out the cleaning for 30 seconds, the entire surface of the sample was rinsed with pure water for 15 seconds.

### COMPARATIVE EXAMPLE 2

The same sample as used in Example 1 was prepared, and the sample was cleaned by a so-called dip method. In particular, the sample was set with its surface to be processed (front surface) facing downwardly in a dip-type cleaning unit. While horizontally rotating the sample at 20 rpm, the sample was immersed in a cleaning liquid, an aqueous citric acid solution containing ethylenediamine diacetic acid (EDTA) and having a pH of more than 3 (pH>3), to carry out cleaning (pre-cleaning) of the sample. After carrying out the cleaning for 60 seconds, the sample was pulled up from the cleaning liquid, and the surface was rinsed with pure water for 15 seconds.

The processing conditions in Example 1 and Comp. Examples 1 and 2 are shown in Table 1 below.

TABLE 1

| | | Com. | |
|---|---|---|---|
| | Example 1 | Example 1 | Comp. Example 2 |
| Chemical supply method | Throwaway | Throwaway | Circulation |
| Flow rate (L/min) | 1 | 6 | 2 |
| Processing time (sec) | 30 | 30 | 60 |

As can be seen from the data in Table 1, an amount of the cleaning liquid (liquid chemical) used for one sample can be made relatively small in Example 1 as compared to Comp. Examples 1 and 2.

Chips were cut off from the respective processed samples of Example 1 and Comp. Examples 1 and 2, and the respective chips were subjected to X-ray photo electron spectroscopy (XPC) analysis. Table 2 shows the relative values of elemental N and O detected by the analysis.

TABLE 2

| | | Comp. | |
|---|---|---|---|
| | Example 1 | Example 1 | Comp. Example 2 |
| Elemental N | 0.1 | 0.6 | 1 |
| Elemental O | 0.4 | 0.5 | 1 |

The values of the elemental N and 0 are considered to be proportional to the residual amount of BTA and the amount of a metal oxide, respectively. Thus, the data in Table 2 demonstrates that the processing of Example 1 is more effective in the removal of BTA or a Cu-BTA complex, as a corrosion inhibitor, and a metal oxide than the processings of Comp. Examples 1 and 2.

### EXAMPLE 2

A 300 mm across patterned wafer, having copper interconnects with exposed surfaces formed by CMP, was prepared as a sample. Benzotriazole (BTA) had been left on surfaces of the copper interconnects after CMP.

A front surface of the sample was cleaned (pre-cleaned), followed by rinsing with pure water, in the same manner as in Example 1. Next, the sample after the pre-cleaning was carried into an electroless plating unit, where the sample was immersed in an electroless plating solution containing an inorganic cobalt salt, an inorganic tungsten salt and DMAB, and having a pH of more than 8 (pH>8) to form a protective film on the surfaces of the copper interconnects. After carrying out the electroless plating for a predetermined time, the sample was pulled up from the electroless plating solution and the entire surface of the sample was immediately rinsed with pure water for 5 seconds. Thereafter, the sample was cleaned and dried.

### COMPARATIVE EXAMPLE 3

The same sample as used in Example 2 was prepared, and a front surface of the sample was cleaned (pre-cleaned), followed by rinsing with pure water, in the same manner as in Comp. Example 1. Thereafter, a protective film was formed on surfaces of interconnects of the sample after cleaning (pre-cleaning) in the same manner as in Example 2, followed by cleaning and drying of the sample.

### COMPARATIVE EXAMPLE 4

The same sample as used in Example 2 was prepared, and a front surface of the sample was cleaned (pre-cleaned), followed by rinsing with pure water, in the same manner as in Comp. Example 2. Thereafter, a protective film was formed on surfaces of interconnects of the sample after cleaning (pre-cleaning) in the same manner as in Example 2, followed by cleaning and drying of the sample.

For the protective films (Co alloy films) formed on the copper interconnects, obtained in Example 2 and Comp. Examples 3 and 4, measurement of film thickness was carried out on typical portions of each protective film using an optical film thickness measuring device. Table 3 shows the results of the measurement in terms of the average film thickness and the unevenness (3σ) of film thickness.

TABLE 3

| | | Comp. | |
|---|---|---|---|
| | Example 2 | Example 3 | Comp. Example 4 |
| Average film thickness (nm) | 12 | 11 | 12 |
| 3σ | 8% | 12% | 15% |

As can be seen from the data in Table 3, the protective film of Example 2 is superior in the in-plane uniformity of film thickness as compared to the protective films of Comp. Examples 3 and 4.

### EXAMPLE 3

The same sample as used in Example 2 was prepared, and a front surface of the sample was cleaned (pre-cleaned), followed by rinsing with pure water, in the same manner as in Example 1. Next, the sample was carried into a catalytic application unit, where the sample was immersed in a catalyst application solution, an aqueous sulfuric acid solution containing PdSO₄ and having a pH of less than 2 (pH<2), and after elapse of a predetermined period of time, the sample was pulled up from the catalyst application solution. Immediately thereafter, the sample surface was rinsed with pure water for 10 seconds. Thereafter, the sample was carried into an electroless plating unit, where the sample was immersed in an electroless plating solution containing an inorganic cobalt salt, an inorganic tungsten salt and a hypophosphite, and having a pH of more than 8 (pH>8) to form a protective film on surfaces of copper interconnects. After carrying out the electroless plating for a predetermined time, the sample was pulled up from the electroless plating solution and the entire surface of the sample was immediately rinsed with pure water for 5 seconds. Thereafter, the sample was cleaned and dried.

### COMPARATIVE EXAMPLE 5

The same sample as used in Example 2 was prepared, and a front surface of the sample was cleaned (pre-cleaned), followed by rinsing with pure water, in the same manner as in Comp. Example 1. Thereafter, a protective film was formed on surfaces of interconnects of the sample after cleaning (pre-cleaning) in the same manner as in Example 3, followed by cleaning and drying of the sample.

### COMPARATIVE EXAMPLE 6

The same sample as used in Example 2 was prepared, and a front surface of the sample was cleaned (pre-cleaned), followed by rinsing with pure water, in the same manner as in Comp. Example 2. Thereafter, a protective film was formed on surfaces of interconnects of the sample after cleaning (pre-cleaning) in the same manner as in Example 3, followed by cleaning and drying of the sample.

For the protective films (Co alloy films) formed on the copper interconnects, obtained in Example 3 and Comp. Examples 5 and 6, measurement of film thickness was carried out on typical portions of each protective film using an optical film thickness measuring device. Table 4 shows the results of the measurement in terms of the average film thickness and the unevenness (3σ) of film thickness.

TABLE 4

| | | Comp. | |
|---|---|---|---|
| | Example 3 | Example 5 | Comp. Example 6 |
| Average film thickness (nm) | 10 | 9 | 10 |
| 3σ | 6% | 9% | 12% |

As can be seen from Table 4, the protective film of Example 3 is superior in the in-plane uniformity of film thickness as compared to the protective films of Comp. Examples 5 and 6.

Measurement of leak current in interconnects was also carried out for the processed samples of Example 3 and Comp. Examples 5 and 6. FIG. 28 shows the distribution of the leak current measured for each sample, together with the leak current distribution in the interconnects of a non-processed sample as a reference. Less shifting of a leak current to larger values is preferred for device performance. As shown in FIG. 28, the leak current in the interconnects, with the protective film formed thereon, of Example 3is more similar to the leak current in the non-processed interconnects as compared to those of Comp. Examples 5 and 6. This demonstrates that the cleaning processing of Example 3 can more effectively remove impurities remaining on the surface of the sample, resulting in the lowest leak current in the interconnects after plating.

According to the present invention, a protective film having a uniform thickness can be formed on surfaces of interconnects by carrying out pre-processing using a combination of the chemical action of a chemical and the mechanical action (scrub cleaning) of a cleaning member to effectively remove a corrosion inhibitor and/or a metal complex remaining on the substrate surface, including the surfaces of the interconnects, and then carrying out catalyst application processing and/or electroless, plating. In addition, the pre-processing or pre-cleaning can be carried out uniformly over the entire surface of the substrate in a short time, e.g., about 5 to 60 seconds, while controlling an amount of the chemical used, e.g., up to one liter.

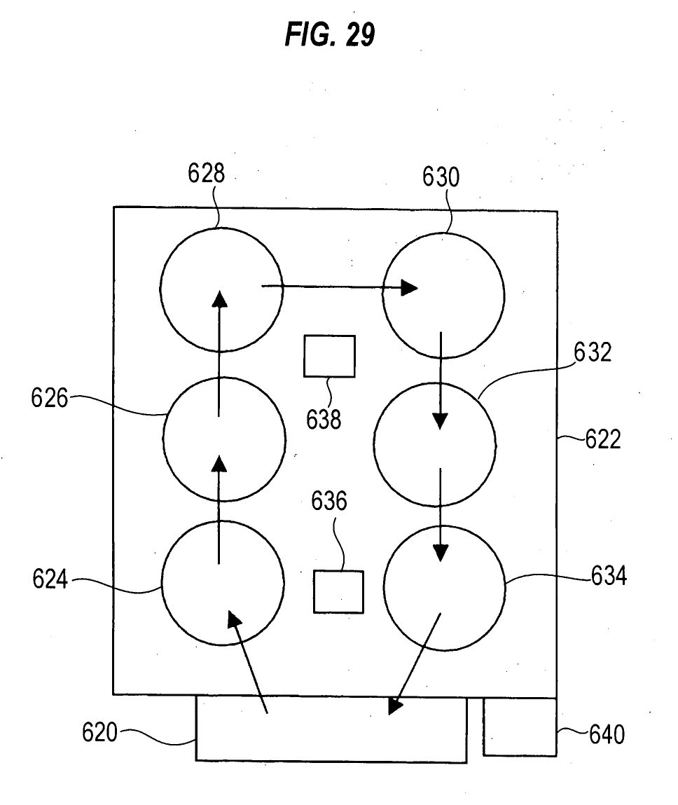

FIG. 29 shows a layout plan view of a substrate processing apparatus according to yet another embodiment of the present invention. As shown in FIG. 29, the substrate processing apparatus includes a loading/unloading unit 620 for mounting therein a substrate cassette in which are housed substrates W (see FIG. 3C) each having interconnects 8 of, e.g., copper formed in trenches 4 formed in a surface.

The substrate processing apparatus also includes a rectangular housing 622 equipped with an air discharge system and, located in the housing 622, a pre-cleaning unit (pre-processing unit) 624 for carrying out pre-cleaning of a substrate as a pre-plating processing, a catalyst application processing unit (pre-processing unit) 626 for carrying out catalyst application processing of the substrate as a pre-plating processing, an electroless plating unit 628 for forming a protective film 9 of, e.g., a CoWP alloy selectively on exposed surfaces of interconnects 8 to which a catalyst has been applied, a roll-type post-cleaning unit 630 for cleaning (post-cleaning) the surface of the substrate, having the protective film 9 selectively formed on the interconnects, by rubbing the substrate surface with a roll (roll sponge or roll brush), a spray-type post-cleaning unit 632 for carrying out cleaning (post-cleaning) of the substrate, having the protective film 9 selectively formed on the interconnects, by spraying a post-cleaning liquid in a mist form toward substantially the entire substrate surface, and a rinsing/drying unit 634 for rinsing with pure water the substrate surface after the post-cleaning, and drying the substrate surface.

Located at positions surrounded by the above units in the housing 622, there are disposed a first transport robot 636 and a second transport robot 638 for transporting the substrate. Further, a control unit 640 is mounted to the sidewall of the housing 622.

Though in this embodiment the pre-cleaning and the catalyst application processing as pre-plating processings are carried out in separate units, it is also possible to carry out these processings in a single common unit. Depending on the type of an alloy of a protective film to be formed, it is possible to omit the catalyst application processing.

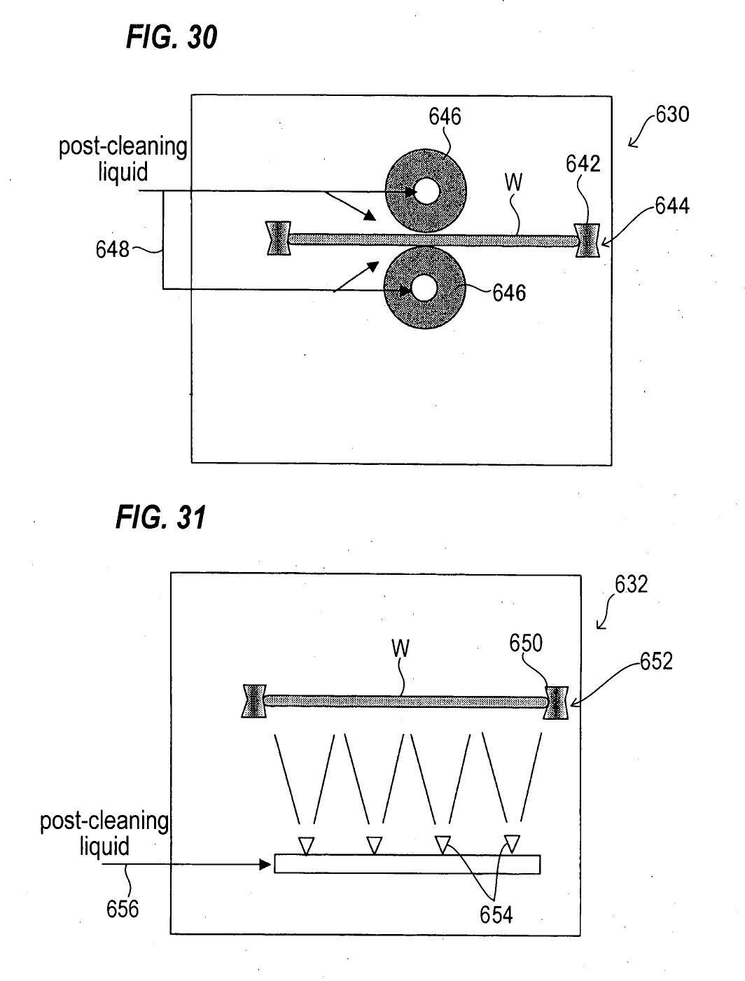

As shown in FIG. 30, the roll-type post-cleaning unit 630 includes a substrate holder 644 comprising a plurality of rollers 642 for detachably holding the peripheral edge of the substrate W and rotating the substrate W, and a pair of long cylindrical rolls (roll sponges or roll brushes) 646 movable closer to or away from the front and back surfaces of the substrate W held by the substrate holder 644. The post-cleaning unit 630 also includes a post-cleaning liquid supply line 648 for supplying a post-cleaning liquid to the front and back surfaces of the substrate W held by the substrate holder 644 and to the interiors of the rolls 646.

In operation, the pair of rollers 642 is rotated on their axes while keeping the rollers 642 in contact with the front and back surfaces of the substrate W, which is held and being rotated by the rollers 642 of the substrate holder 644, and supplying the post-cleaning liquid from the post-cleaning liquid supply line 648 to the front and back surfaces of the substrate W and to the interiors of the rolls 646, thereby scrub-cleaning the front and back surfaces of the substrate W.

An organic acid containing a surfactant and having a pH of 2 to 5 or pure water having a pH of 6 to 8 can be used as the post-cleaning liquid. The surfactant preferably is a nonionic surfactant, e.g., polyoxyalkylene alkyl ether, such as polyoxyalkylene alkyl ether, or an anionic surfactant. An alkaline solution containing TMAH and having a pH of 7 to 12 may also be used as the post-cleaning liquid.

As shown in FIG. 31, the spray-type post-cleaning unit 632 includes a substrate holder 652 comprising a plurality of rollers 650 for detachably holding the peripheral edge of the substrate W and rotating the substrate, and spray nozzles 654 for spraying a post-cleaning liquid in a mist form toward substantially the entire surface of the substrate W held by the substrate holder 652. In this embodiment, the substrate holder 652 holds the substrate W with its front surface (with the interconnects formed) facing downwardly, and the spray nozzles 654 are located below the substrate holder 652 and oriented upward. The distance from the front ends (upper ends) of the spray nozzles 654 to the substrate W held by the substrate holder 652 is, for example, 1 to 20 cm. The spray nozzles 654 a reconnected to a post-cleaning liquid supply line 656.

The number of the spray nozzles 654 is, for example, 1 to 30, and preferably 10 to 20. This can spray the post-cleaning liquid more uniformly onto substantially the entire surface of the substrate W. The average particle diameter of the post-cleaning liquid sprayed in a mist form from the spray nozzles 654 is, for example, 50 to 1000 μm, and the flow rate of the pre-cleaning liquid is, for example, 0.5 to 10 L/min. This can provide the post-cleaning solution, sprayed in a mist form from the spray nozzles 654, with a kinetic energy necessary for effectively removing a film-shaped metal residue and the like remaining on an insulating film.

In operation, while rotating the substrate W, which is held face down by the rollers 650 of the substrate holder 652, e.g., at a rotational speed of 1 to 500 rpm, the cleaning liquid is sprayed in a mist form from the spray nozzles 654 toward the entire surface (lower surface) of the substrate W. The surface of the substrate W can be cleaned by thus utilizing the kinetic energy of the cleaning liquid as well as its chemical energy. Especially when spraying the post-cleaning liquid in a mist form from a position at a distance of 1 to 20 cm from the substrate W toward substantially the entire surface of the substrate W while rotating the substrate W at a rotational speed of 1 to 500 rpm, the post-cleaning liquid in a mist form can be sprayed more uniformly onto substantially the entire surface of the substrate W.

As with the above-described roll-type post-cleaning unit 630, an organic acid containing a surface and having a pH of 2 to 5 or pure water having a pH of 6 to 8 can be used as the post-cleaning liquid. The surfactant preferably is a nonionic surfactant, e.g., polyoxyalkylene alkyl ether, such as polyoxyalkylene alkyl ether, or an anionic surfactant. An alkaline solution containing TMAH and having a pH of 7 to 12 may also be used as the post-cleaning liquid.

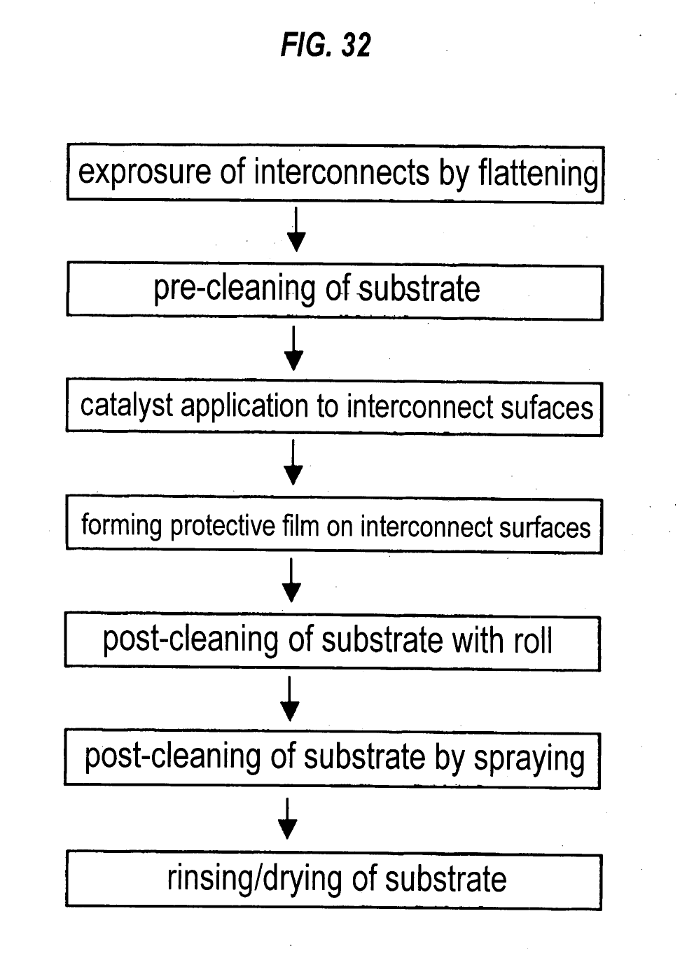

A series of electroless plating processings by the substrate processing apparatus will now be described with reference also to FIG. 32. The following description illustrates the case of selectively forming a protective film 9 of a COWP alloy to protect interconnects 8, as shown in FIG. 3D.

First, one substrate W is taken by the first transport robot 636 out of a substrate cassette which is mounted in the loading/unloading unit 620 and in which are housed substrates W, such as semiconductor wafers which have undergone flattening processing, such as CMP, to expose the interconnects 8 (see FIG. 3C), and the substrate W is transported to the pre-cleaning unit 624. In the pre-cleaning unit 624, pre-cleaning of the substrate W is carried out, for example, by immersing the substrate W in dilute sulfuric acid or an organic acid at room temperature for about one minute, or by spraying such a cleaning liquid toward the rotating substrate W, thereby removing impurities, such as a metal oxide film, a CMP residue such as copper, etc. on a surface of an insulating film 2.

After cleaning (rinsing) the surface of the substrate W, e.g., with pure water, the substrate W is transported to the catalyst application processing unit 626, where Pd as a catalyst is attached to surfaces of interconnects 8 to activate exposed surfaces of interconnects 8, for example, by immersing the substrate W in a mixed solution of PdCl₂/HCl or PdSO₄/H₂SO₄ at room temperature for about one minute, or by spraying such a catalyst application solution toward the surface of the rotating substrate.

After cleaning (rinsing) the surface of the substrate W, e.g., with pure water, the substrate W is transported to the electroless plating unit 628, where selective electroless plating is carried out on the activated surfaces of interconnects 8, for example, by immersing the substrate W in a CoWP plating solution at 80° C. for about 120 seconds, followed by cleaning (rinsing) of the surface of the substrate W, e.g., with pure water, thereby forming a protective film 9 of a COWP alloy to protect the interconnects 8 selectively on the exposed surfaces of the interconnects 8, as shown in FIG. 3D.

The substrate W with the protective film 9 formed thereon is transported to the roll-type post-cleaning unit 630, where the front and back surfaces of the substrate W are scrub-cleaned (post-cleaned) by the rolls 646 by rotating the pair of rollers 642 on their axes while keeping them in contact with the front and back surfaces of the substrate W, which is held and being rotated by the rollers 642 of the substrate holder 644, and supplying a post-cleaning liquid from the post-cleaning liquid supply line 648 to the front and back surfaces of the substrate W and to the interiors of the rolls 646.

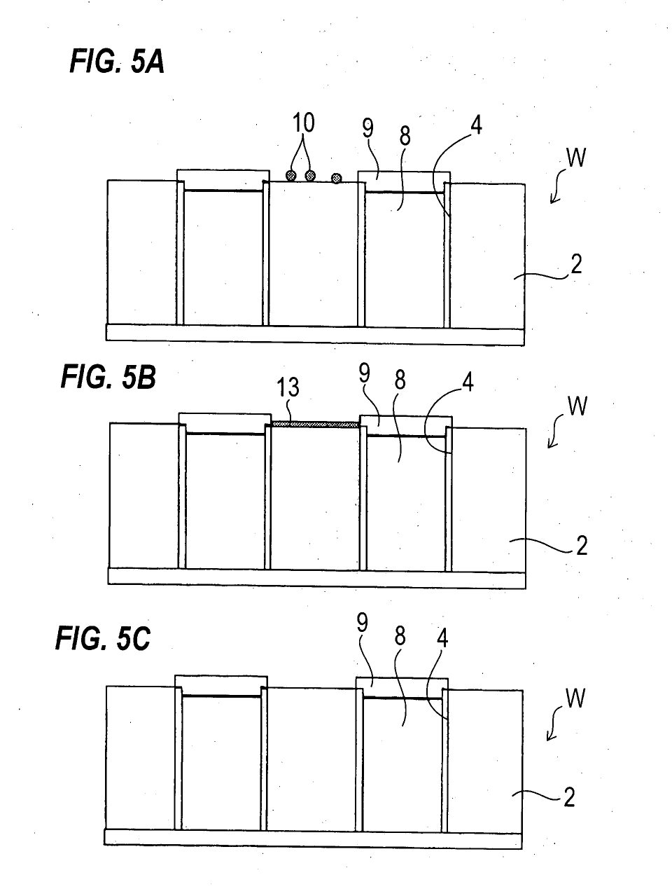

The roll cleaning by the roll-type post-cleaning unit 630 mainly removes a particulate metal residue 10, shown in FIG. 5A, having a diameter of the order of several nm to several tens of nm, remaining on the surface of the insulating film 2 after the formation of the protective film 9 on the surfaces of the interconnects 8 by electroless plating. Therefore, the pressure applied on the rolls 646 can be lowered to such a level as to prevent excessive removal of the protective film 9.

The substrate W after the roll cleaning is then transported to the spray-type post-cleaning unit 632, where the surface of the substrate W is cleaned (post-cleaned) by spraying a cleaning liquid in a mist form from the spray nozzles 654 toward the entire surface (lower surface) of the substrate W, held with the front surface facing downwardly by the rollers 650 of the substrate holder 652, while rotating the substrate W at a rotational speed of, e.g., 1 to 500 rpm.

The cleaning by the spray-type post-cleaning unit 632 mainly removes a film-shaped metal residue 13, shown in FIG. 5B, having a thickness of the order of several nm to ten and several nm, remaining on the surface of the insulating film 2 after the formation of the protective film 9 on the surfaces of the interconnects 8 by electroless plating. The film-shaped metal residue 13 is generally difficult to remove by roll cleaning. According to this embodiment, by carrying out cleaning (post-cleaning) of the substrate W by spraying a post-cleaning liquid in a mist form toward the surface of the substrate W, i.e., by allowing liquid droplets of the post-cleaning liquid, each having a kinetic energy, to collide against the surface of the substrate W, the kinetic energy of the cleaning liquid as well as its chemical energy can be utilized to effectively remove metal residues, including the film-shaped metal residue 13, etc. remaining on the insulating film 2. In addition, re-adhesion of a dissolved portion of the protective film 9 to the insulating film 2 can be prevented. Further, by spraying the post-cleaning liquid toward substantially the entire surface of the substrate W, the entire surface of the substrate W can be cleaned more uniformly with the post-cleaning liquid.

By thus mainly removing the particulate metal residue 10 having a diameter of the order of several nm to several tens of nm, remaining on the surface of the insulating film 2, by the roll-type post-cleaning unit 630, and then mainly removing the film-shaped metal residue 13 having a thickness of the order of several nm to ten and several nm, remaining on the surface of the insulating film 2, by the spray-type post-cleaning unit 632, metal residues can be completely removed from the surface of the insulating film 2, as shown in FIG. 5C.

Next, the substrate after the post-cleaning is transported to the rinsing/drying unit 634, where the surface of the substrate W is rinsed with pure water by supplying pure water to the surface of the substrate W, and then the substrate W is spin-dried by rotating the substrate W at a high speed. The substrate W after spin drying is returned by the first transport robot 636 to the substrate cassette mounted in the loading/unloading unit 620.

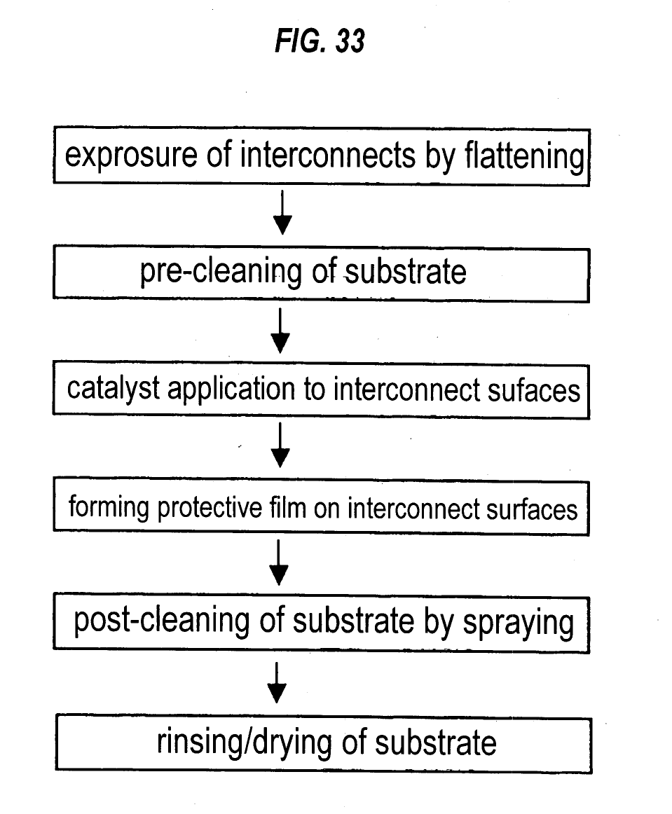

In this embodiment, the roll-type post-cleaning unit 630 and the spray-type post-cleaning unit 632 are provided to remove both the particulate metal residue 10 having a diameter of the order of several nm to several tens of nm and the film-shaped metal residue 13 having a thickness of the order of several nm to ten and several nm, remaining on the surface of the insulating film 2. In the case of mainly removing only the film-shaped metal residue 13 having a thickness of the order of several nm to ten and several nm, remaining on the surface of the insulating film 2, it is possible to omit the roll-type post-cleaning unit 630 and not to carry out post-cleaning of a substrate by a roll, as shown in FIG. 33.

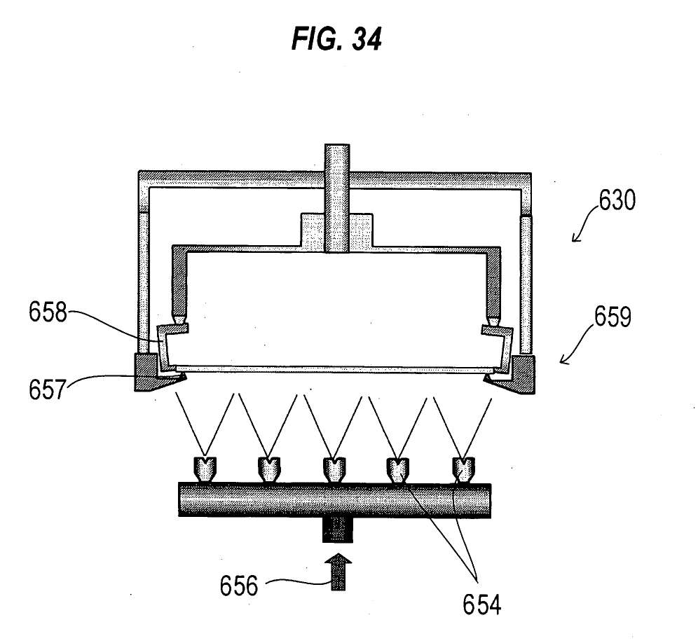

It is also possible to use as a spray-type post-cleaning unit 632 a unit, as shown in FIG. 34, comprising a substrate holder 659 which includes a seal ring 657 and a pressing member 658, and holds a substrate W with its front surface facing downwardly while sealing a peripheral portion of the substrate W with the seal ring 658, and spray nozzles 654 disposed below the substrate holder 659.

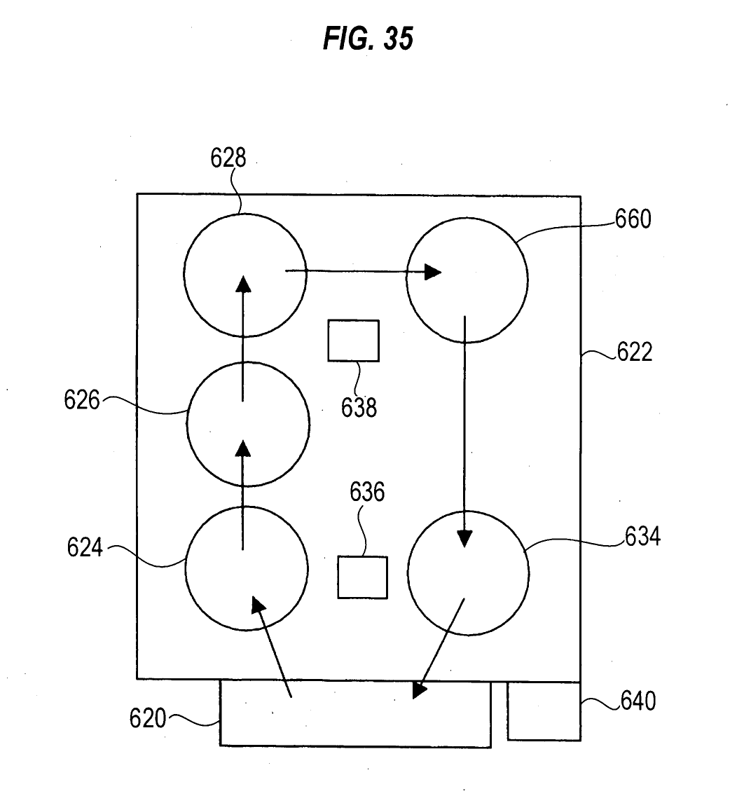

FIG. 35 shows a layout plan view of a substrate processing apparatus according to yet another embodiment of the present invention. The substrate processing apparatus shown in FIG. 35 differs from the substrate processing apparatus shown in FIG. 29 in that instead of the roll-type post-cleaning unit 630 and the spray-type post-cleaning unit 632, shown in FIG. 29, a post-cleaning unit 660 having a roll post-cleaning function and a spray post-cleaning function is disposed in the housing 622.

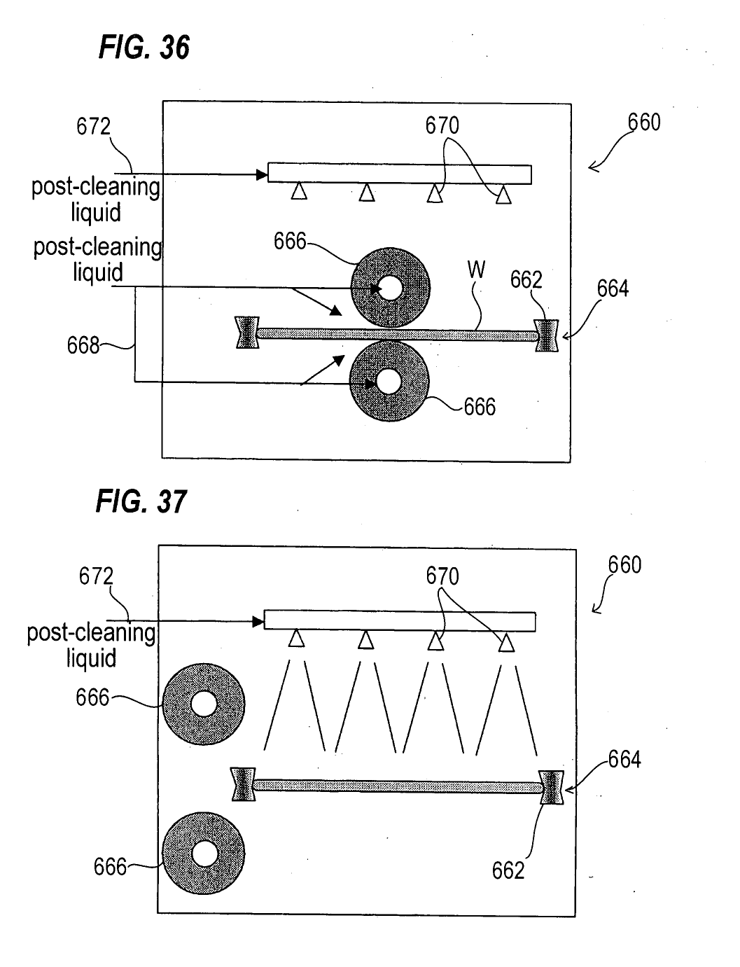

As shown in FIGS. 36 and 37, the post-cleaning unit 660 includes a substrate holder 664 comprising a plurality of rollers 662 for detachably holding the peripheral edge of the substrate W and rotating the substrate W, and a pair of long cylindrical rolls (roll sponges or roll brushes) 666 movable closer to or away from the front and back surfaces of the substrate W held by the substrate holder 664, and retreatable. The post-cleaning unit 660 also includes a post-cleaning liquid supply line 668 for supplying a post-cleaning liquid to the front and back surfaces of the substrate W held by the substrate holder 664 and to the interiors of the rolls 666. In this embodiment, the substrate holder 664 holds the substrate W with its front surface (with the interconnects formed) facing upwardly.

Above the substrate W held by the substrate holder 664 are disposed downwardly-oriented spray nozzles 670 for spraying a post-cleaning liquid in a mist form toward substantially the entire surface of the substrate W held by the substrate holder 664. A post-cleaning liquid supply line 672 is connected to the spray nozzles 670.

In operation of the post-cleaning unit 660, as shown in FIG. 36, the pair of rolls 666 are rotated on their axes while keeping the rolls 666 in contact with the front and back surfaces of the substrate W, which is held and being rotated by the rollers 662 of the substrate holder 664, and supplying a post-cleaning liquid from the post-cleaning liquid supply line 668 to the front and back surfaces of the substrate W and to the interiors of the rolls 666, thereby scrub-cleaning (post-cleaning) the front and back surfaces of the substrate w by the rolls 666. Thereafter, as shown in FIG. 37, while rotating the substrate W, held face up by the rollers 662 of the substrate holder 664, at a rotational speed of, e.g., 1 to 500 rpm, a cleaning liquid is sprayed in a mist form from the spray nozzles 670 toward the entire surface (lower surface) of the substrate W, whereby the surface of the substrate W can be cleaned (post-cleaned).

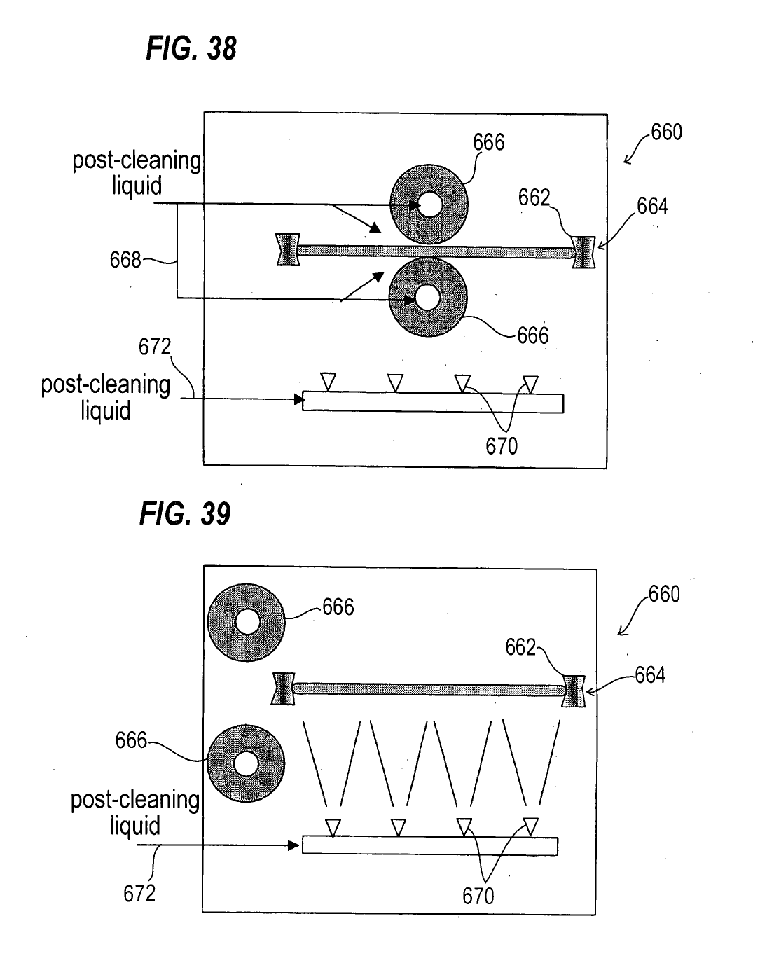

As shown in FIGS. 38 and 39, it is also possible to hold the substrate W with its front surface (with the interconnects formed) facing downwardly by the substrate holder 664 and to spray the post-cleaning liquid in a mist form upwardly toward substantially the entire surface of the substrate W held by the substrate holder 664 from the spray nozzles 670 oriented upwardly and disposed below the substrate W held by the substrate holder 664.

Though a COWP alloy is used for the protective film 9 in the illustrated embodiments, it is also possible to use CoP, CoWP, CoB, NiWP, NiP, NiWB, NiB, etc. for a protective film. Further, though copper is used as an interconnect material in the illustrated embodiments, a copper alloy, silver, a silver alloy, gold, a gold alloy, etc. may also be used.

### EXAMPLE 4

Using the substrate processing apparatus shown in FIG. 29, a protective film was formed on the surface of interconnects formed on a 300 mm wafer. In particular, a wafer in a dry state was taken out of a substrate cassette by the transport robot, and the wafer was carried into the pre-cleaning unit, where the wafer was set with its front surface facing downwardly. While rotating the wafer at 20 rpm, a cleaning liquid (chemical) based on an organic acid was sprayed from the spray nozzles onto the entire surface of the wafer to carry out pre-cleaning of the wafer surface. After carrying out the pre-cleaning for 30 seconds, the wafer surface was rinsed with pure water for 15 seconds.

Thereafter, the wafer was taken out of the pre-cleaning unit and carried into the catalyst application unit, where the wafer was set with its front surface facing downwardly. While rotating the wafer at 20 rpm, a catalyst-containing liquid chemical, an aqueous sulfuric acid solution containing PdSO₄, was sprayed from the spray nozzles toward the entire surface of the wafer to carry out catalyst application processing. After carrying out the processing for 20 seconds, the wafer surface was rinsed with pure water for 15 seconds.

Next, the wafer was taken out of the catalyst application processing unit and carried into the electroless plating unit. The wafer was immersed in a plating solution in the plating tank of the electroless plating unit to carry out electroless plating of the wafer surface. After elapse of a predetermined plating time, the wafer was pulled up from the plating solution, and the entire wafer surface was immediately rinsed with pure water for 5 seconds.

Next, the wafer was carried into the spray-type post-cleaning unit, where the wafer was set with its front surface facing downwardly. While rotating the wafer at 20 rpm, a post-cleaning liquid (chemical) was sprayed from the spray nozzles toward the entire surface of the wafer, thereby carrying outpost-cleaning of the wafer surface for 30 seconds. An organic acid solution containing a surfactant and having a pH of 2 to 4, with the etching rate for the protective film (alloy) formed being 0.5 to 5 nm/min, was used as the post-cleaning liquid. The spray pressure of the spray nozzles was 100 to 130 kPa, and the flow rate of the post-cleaning liquid was 6 L/min. Thereafter, the wafer surface was rinsed with pure water for 15 seconds. The wafer was then taken out of the spray-type post-cleaning unit and transported to the rinsing/drying unit, where the wafer surface was rinsed with pure water for 5 seconds, and the wafer was then rotated at a high speed to dry the wafer surface. Thereafter, the wafer was returned to the substrate cassette.

### EXAMPLE 5

Prior to cleaning the wafer in the spray-type post-cleaning unit, the wafer was set with its front surface facing upwardly in the roll-type post-cleaning unit. While rotating the wafer at 110 rpm, pure water was supplied to the front surface of the wafer for 5 seconds to wet the entire surface with pure water. Thereafter, while rotating the roll at 100 rpm, it was brought into contact with the wafer surface. Simultaneously with the contact of the roll with the wafer surface, a post-cleaning liquid (chemical) began to be supplied to the wafer surface, thereby carrying out roll-cleaning of the wafer surface for 30 seconds. An organic acid solution containing a surfactant and having a pH of 2 to 4, with the etching rate for the protective film (alloy) formed being 0.5 to 5 nm/min, was used as the post-cleaning liquid. Thereafter, the roll was separated from the wafer surface, and the wafer surface was immediately rinsed with pure water for 15 seconds. Thereafter, the wafer was taken out of the roll-type post-cleaning unit, and the wafer was then carried into the spray-type post-cleaning unit, where post-cleaning of the wafer was carried out in the same manner as in Example 4.

### COMPARATIVE EXAMPLE 7

Electroless plating of the surface of the wafer was carried out in the electroless plating unit in the same manner as in Example 4. Thereafter, the wafer was pulled up from the plating solution, and the entire wafer surface was immediately rinsed with pure water for 5 seconds. The wafer was then taken out of the electroless plating unit and transported to the rinsing/drying unit, where the wafer surface was rinsed with pure water for 5 seconds, and the wafer was then rotated at a high speed to dry the wafer surface. Thereafter, the wafer was returned to the substrate cassette.

### COMPARATIVE EXAMPLE 8

Electroless plating of the surface of the wafer was carried out in the electroless plating unit in the same manner as in Example 4. Thereafter, the wafer was pulled up from the plating solution, and the entire wafer surface was immediately rinsed with pure water for 5 seconds. The wafer was then taken out of the electroless plating unit and carried into the roll-type post-cleaning unit, in which the wafer was set with its front surface facing upwardly. While rotating the wafer at 110 rpm, pure water was supplied to the front surface of the wafer for 5 seconds to wet the entire surface with pure water. Thereafter, while rotating the roll at 100 rpm, it was brought into contact with the wafer surface. Simultaneously with the contact of the roll with the wafer surface, a post-cleaning liquid (chemical) began to be supplied to the wafer surface, thereby carrying out roll-cleaning of the wafer surface for 30 seconds. An organic acid solution containing a surfactant and having a pH of 2 to 4, with the etching rate for the protective film (alloy) formed being 0.5 to 5 nm/min, was used as the post-cleaning liquid. Thereafter, the roll was separated from the wafer surface, and the wafer surface was immediately rinsed with pure water for 15 seconds. Thereafter, the wafer was taken out of the roll-type post-cleaning unit and transported to the rinsing/drying unit, where the wafer surface was rinsed with pure water for 5 seconds, and the wafer was then rotated at a high speed to dry the wafer surface. Thereafter, the wafer was returned to the substrate cassette.

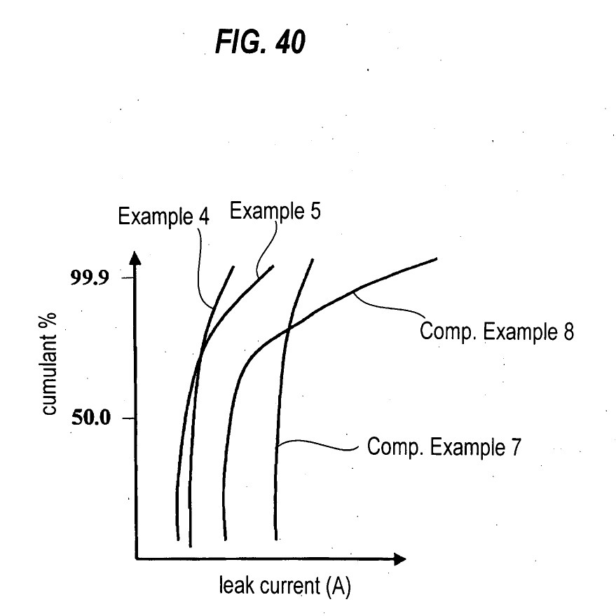

For the processed wafers obtained in Examples 4 and 5 and Comp. Examples 7 and 8, leak currents between interconnects were measured. FIG. 40 shows the distribution of the leak current measured for each wafer.

As shown in FIG. 40, though the leak current between interconnects of the wafer of Comp. Example 8 is partly lower than that of the wafer of Comp. Example 7, the former leak current shifts largely to higher valves and becomes higher than the latter leak current. This is considered tone due to the fact that those portions of the protective film (alloy) on interconnects, which had been removed by the roll cleaning, re-adhered to the insulating film. In contrast thereto, the leak currents between interconnects of the wafers of Examples 4 and 5 are both significantly lower than those of Comp. Examples 7 and 8. This is considered to be due to the fact that a film-shaped metal residue on the insulating film was effectively removed, i.e., the selectivity of the protective film was enhanced, in the wafers of Examples 4and 5.

For the processed wafers obtained in Examples 5 and 6, and Comp. Examples 7 and 8, measurement of the number of surface defects was also carried out, the results of which are shown in Table 5.

TABLE 5

| | Number of defects |
|---|---|
| Wafer processing conditions | (relative value) |
| Example 4 | 62 |
| Example 5 | 22 |
| Comp. Example 7 | 100 |
| Comp. Example 8 | 59 |

The number of surface defects of the wafer of Example 4 is nearly equal to that of the wafer of Comp. Example 8, and much smaller than that of the wafer of Comp. Example 7. This shows that the post-cleaning processing of Example 4 is effective in the removal of particulate metal residue on the insulating film comparably to the processing of Comp. Example 8. The number of surface defects of the wafer of Example 5 is significantly smaller than those of the wafers of Comp. Example 8 and Example 4. This shows that the combination of roll cleaning and spray cleaning is most effective in decreasing the number of surface defects.

According to the present invention, a film-shaped metal residue remaining on an insulating film, which is generally difficult to remove by roll cleaning, can be effectively removed by utilizing the kinetic energy of a cleaning liquid as well as its chemical energy. Further, by spraying the post-cleaning liquid toward substantially the entire surface of the substrate, the entire substrate surface can be cleaned more uniformly with the post-cleaning liquid.

While the present invention has been described with reference to the preferred embodiments thereof, it is understood that the present invention is not limited to the particular embodiments, but various modifications may be made there in within the technical concept of the invention.

What is claimed is:

1. A substrate processing method comprising:
preparing a substrate having metal interconnects formed in an electric insulator;
carrying out pre-processing of the substrate by bringing a cleaning member into contact with the front surface or both surfaces of the substrate in a wet state and moving them relative to each other while supplying a pre-processing liquid to the front surface or both surfaces of the substrate; and then
forming a protective film selectively on surfaces of the metal interconnects by bringing the front surface of the substrate into contact with an electroless plating solution.

2. The substrate processing method according to claim 1, wherein the surface of the substrate after the pre-processing is rinsed with pure water, and the substrate surface is brought into contact with the electroless plating solution before the substrate surface becomes fully dry.

3. A substrate processing method comprising:
preparing a substrate having metal interconnects formed in an electric insulator;
carrying out pre-cleaning of the substrate by bringing a cleaning member into contact with the front surface or both surfaces of the substrate in a wet state and moving them relative to each other while supplying a pre-cleaning liquid to the front surface or both surfaces of the substrate;
applying a catalyst to surfaces of the metal interconnects by bringing the substrate surface after the pre-cleaning into contact with a catalyst application solution; and then
forming a protective film selectively on the surfaces of the metal interconnects by bringing the front surface of the substrate into contact with an electroless plating solution.

4. The substrate processing method according to claim 3, wherein the surface of the substrate after the pre-cleaning is rinsed with pure water, and the substrate surface is brought into contact with the catalyst application solution before the substrate surface becomes fully dry.

5. A substrate processing apparatus, comprising:
a pre-processing unit for carrying out pre-processing of a substrate by bringing a cleaning member into contact with a front surface or both surfaces of the substrate in a wet state and moving them relative to each other while supplying a pre-processing liquid to the front surface or both surfaces of the substrate; and
an electroless plating unit for forming a protective film selectively on surfaces of metal interconnects by bringing the front surface of the substrate into contact with an electroless plating solution.

6. The substrate processing apparatus according to claim 5, further comprising:
a cleaning unit for cleaning the substrate by immersing the substrate in a cleaning liquid or by jetting a cleaning liquid toward the substrate.

7. The substrate processing apparatus according to claim 5, wherein the cleaning member is formed of a porous polyvinyl alcohol having a continuous pore structure or a fluororesin.

8. The substrate processing apparatus according to claim 5, wherein the cleaning member is a roll-shaped brush centrally having a rotating shaft.

9. A substrate processing apparatus, comprising:
a pre-processing unit for carrying out pre-processing of a substrate by bringing a cleaning member into contact with a front surface or both surfaces of the substrate in a wet state and moving them relative to each other while supplying a pre-processing liquid to the front surface or both surfaces of the substrate;
a catalyst application unit for applying a catalyst to surfaces of the metal interconnects by bringing the surface of the substrate after the pre-cleaning into contact with a catalyst application solution; and
an electroless plating unit for forming a protective film selectively on the surfaces of the metal interconnects by bringing the front surface of the substrate in to contact with an electroless plating solution.

10. The substrate processing apparatus according to claim 9, further comprising:
a cleaning unit for cleaning the substrate by immersing the substrate in a cleaning liquid or by ejecting a cleaning liquid toward the substrate.

11. The substrate processing apparatus according to claim 9, wherein the cleaning member is formed of a porous polyvinyl alcohol having a continuous pore structure or a fluororesin.

12. The substrate processing apparatus according to claim 9, wherein the cleaning member is a roll-shaped brush centrally having a rotating shaft.

13. A substrate processing method comprising:
preparing a substrate having metal interconnects formed in an insulating film;
forming a protective film selectively on exposed surfaces of the metal interconnects by electroless plating;
carrying out post-cleaning of the substrate by spraying a post-cleaning liquid in a mist form toward substantially the entire surface of the substrate with the protective film selectively formed thereon; and
rinsing with pure water the surface of the substrate after the post-cleaning and drying the substrate surface.

14. The substrate processing method according to claim 13, wherein the average particle diameter of the post-cleaning liquid sprayed in a mist form is 50 to 1000 μm, and the flow rate of the post-cleaning liquid is 0.5 to 10 L/min.

15. The substrate processing method according to claim 13, wherein the post-cleaning liquid is sprayed in a mist form toward substantially the entire surface of the substrate from a position at a distance of 1 to 20 cm from the substrate while rotating the substrate at a rotational speed of 1 to 500 rpm.

16. The substrate processing method according to claim 13, wherein the post-cleaning liquid is an organic acid containing a surfactant and having a pH of 2 to 5 or pure water having a pH of 6 to 8.

17. The substrate processing method according to claim 13, wherein the post-cleaning liquid is an alkaline solution containing TMAH and having a pH of 7 to 12.

18. A substrate processing method comprising:
preparing a substrate having metal interconnects formed in an insulating film;
forming a protective film selectively on exposed surfaces of the metal interconnects by electroless plating;
carrying out first post-cleaning of the substrate by rubbing with a roll the surface of the substrate with the protective film selectively formed thereon;
carrying out second post-cleaning of the substrate by spraying a post-cleaning liquid in a mist form toward substantially the entire surface of the substrate; and
rinsing with pure water the surface of the substrate after the post-cleaning and drying the substrate surface.

19. The substrate processing method according to claim 18, wherein the average particle diameter of the post-cleaning liquid sprayed in a mist form is 50 to 1000 μm, and the flow rate of the post-cleaning liquid is 0.5 to 10 L/min.

20. The substrate processing method according to claim 18, wherein the post-cleaning liquid is sprayed in a mist form toward substantially the entire surface of the substrate from a position at a distance of 1 to 20 cm from the substrate while rotating the substrate at a rotational speed of 1 to 500 rpm.

21. The substrate processing method according to claim 18, wherein the post-cleaning liquid is an organic acid containing a surfactant and having a pH of 2 to 5 or pure water having a pH of 6 to 8.

22. The substrate processing method according to claim 18, wherein the post-cleaning liquid is an alkaline solution containing TMAH and having a pH of 7 to 12.

23. A substrate processing apparatus, comprising:
a pre-processing unit for carrying out pre-plating processing of a surface of a substrate having metal interconnects formed in an insulating film;
an electroless plating unit for forming a protective film selectively on exposed surfaces of the metal interconnects formed in the substrate surface which has undergone the pre-plating processing in the pre-processing unit;
a spray-type post-cleaning unit for post-cleaning the surface of the substrate with the protective film formed thereon by spraying a post-cleaning liquid in a mist form toward substantially the entire substrate surface; and
a rinsing/drying unit for rinsing with pure water the surface of the substrate after the post-cleaning, and drying the substrate surface.

24. The substrate processing apparatus according to claim 23, wherein the spray-type post-cleaning unit includes:
a substrate holder for rotatably holding the substrate with its front surface facing downwardly; and
a spray nozzle, disposed below the substrate holder, for spraying the post-cleaning liquid in a mist form toward the surface of the substrate in rotation.

25. The substrate processing apparatus according to claim 23, further comprising:
a roll-type post-cleaning unit for cleaning the surface of the substrate with the protective film formed there on by rubbing the substrate surface with a roll.

26. A substrate processing apparatus, comprising:
a pre-processing unit for carrying out pre-plating processing of a surface of a substrate having metal interconnects formed in an insulating film;
an electroless plating unit for forming a protective film selectively on exposed surfaces of the metal interconnects formed in the substrate surface which has undergone the pre-plating processing in the pre-processing unit;
a post-cleaning unit for post-cleaning the surface of the substrate with the protective film formed thereon by rubbing the substrate surface with a roll, and post-cleaning the substrate surface by spraying a post-cleaning liquid in a mist form toward substantially the entire substrate surface; and
a rinsing/drying unit for rinsing with pure water the surface of the substrate after the post-cleaning, and drying the substrate surface.

27. The substrate processing apparatus according to claim 26, wherein the post-cleaning unit includes:
a substrate holder for rotatably holding the substrate;
rolls movable closer to or away from a front and back surfaces of the substrate held by the substrate holder; and
a spray nozzle for spraying the post-cleaning liquid in a mist form toward the surface of the substrate in rotation.
